(19) United States
(12) Patent Application Publication
(10) Pub. No.: US 2026/0096132 A1
(43) Pub. Date: Apr. 2, 2026

(54) Structure and Method for Semiconductor Devices With Self-Protecting Insulator and Backside Contact

(71) Applicant: Taiwan Semiconductor Manufacturing Company, Ltd., Hsin-Chu (TW)

(72) Inventors: Tsung-Lin LEE, Hsinchu City (TW); Chih Chieh YEH, Taipei City (TW); Choh Fei YEAP, Hsinchu (TW)

(21) Appl. No.: 19/069,409

(22) Filed: Mar. 4, 2025

Related U.S. Application Data
(60) Provisional application No. 63/699,877, filed on Sep. 27, 2024.

(51) Int. Cl. H10D 30/00; H10D 30/01; H10D 62/10; H10D 64/01

(52) U.S. Cl. CPC H10D 30/507; H10D 30/0196; H10D 62/116; H10D 64/017

(57) ABSTRACT

The present disclosure provides a method that includes forming a stack including first and second semiconductor layers over a substrate, wherein the first and second semiconductor layers have different compositions and alternate with one another; patterning the stack to form active regions; forming an isolation structure to surround the active regions; forming a hard mask on the isolation structure; forming a dummy gate structure over the stack; recessing source/drain regions of the stack, resulting in source/drain trenches; selectively removing the second semiconductor layers, resulting in first gaps among the first semiconductor layers; forming dielectric interposers in the first gaps; performing a first etching process to laterally recess the dielectric interposers, resulting in second gaps; forming inner spacers in the second gaps; forming source/drain features in the source/drain trenches; removing the dummy gate structure; and removing a subset of the dielectric interposers while bottommost dielectric interposers remain.

### PRIORITY

This application claims the benefit to U.S. Provisional Application Ser. No. 63/699,877 filed Sep. 27, 2024, the entire disclosures of which is incorporated herein by reference. This application is also related to the U.S. Patent Application with Attorney Docket No. 24061.5065US01, the entire disclosures of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of IC processing and manufacturing, and for these advancements to be realized, similar developments in IC processing and manufacturing are needed.

For example, backside contacts are formed on the backside of the substrate to make electric connections to source/drain (S/D) features. However, such as contacts may have overlay shift and with misalignments to the corresponding S/D features, and being landing on the gate electrodes, causing short issues. Therefore, although conventional IC devices have been generally adequate for their intended purposes, they are not satisfactory in every respect.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C and 1D are flow charts of an example method for fabricating an embodiment of a GAA device according to some embodiments of the present disclosure;

FIGS. 2A to 7A, 9A to 17A and 24A to 25A are top views of GAA devices of the present disclosure constructed at various fabrication stages according to some embodiments of the present disclosure;

FIGS. 2B to 7B, 9B to 17B and 24A to 25A are cross sectional views of GAA devices of the present disclosure along the line A-A′ in FIGS. 2A to 7A, 9A to 17A and 24A to 25A, respectively, according to some embodiments of the present disclosure;

FIGS. 2C to 7C, 9C to 17C and 24C to 25C are cross sectional views of a GAA device of the present disclosure along the line B-B′ in FIGS. 2A to 7A, 9A to 17A and 24A to 25A, respectively, according to some embodiments of the present disclosure;

FIGS. 2D to 7D, 9D to 17D and 24D to 25D are cross sectional views of a GAA device of the present disclosure along the line C-C′ in FIGS. 2A to 7A, 9A to 17A and 24A to 25A, respectively, according to some embodiments of the present disclosure;

FIGS. 8A to 8H are cross-sectional views of example methods for fabricating various embodiments of a GAA device according to some embodiments of the present disclosure;

FIGS. 18 to 20 and 23 are cross sectional views of GAA devices of the present disclosure constructed at according to some embodiments of the present disclosure;

FIG. 21 is a flow chart of an example method for fabricating an embodiment of a GAA device according to some embodiments of the present disclosure; and

FIGS. 22A to 22H are cross-sectional views of example methods for fabricating various embodiments of a GAA device according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” may encompass the dimension range from 4.5 nm to 5.5 nm.

The disclosed device structure and the method making the same are related to an integrated circuit (IC) structure, such as 3D inter-chips (3DIC), system on chip (SoC), system on integrated chips (SoIC), other proper structure or a combination thereof. The disclosed IC structure is further related to an integrated circuit (IC) structure having multi-gate field effect transistors (FETs), especially, FETs formed on multiple channels vertically stacked, such as nano-sheet devices, such as nano-sheet FETs, gate-all-around (GAA) FETs, other suitable multi-gate devices, or a combination thereof. In the following description, nano-sheet device and GAA device are interchangeably used. A GAA device includes any device that has its gate structure, or portions thereof, formed around all-sides of a channel region (e.g. surrounding a portion of a channel region). In some instances, a GAA device may also be referred to as a quad-gate device where the channel region has four sides and the gate structure is formed on all four sides. The channel region of a GAA device may include one or more semiconductor layers, each of which may be in one of many different shapes, such as wire (or nanowire), sheet (or nanosheet), bar (or nano-bar), and/or other suitable shapes. In embodiments, the channel region of a GAA device may have multiple horizontal semiconductor layers (such as nanowires, nanosheets, or nano-bars) (hereinafter collectively referred to as “nanochannels”) vertically spaced, making the GAA device a stacked horizontal GAA device. The GAA devices presented herein may be a complementary metal-oxide-semiconductor (CMOS) GAA device, a p-type metal-oxide-semiconductor (pMOS) GAA device, an n-type metal-oxide-semiconductor (nMOS) GAA device, or a complementary field-effect transistor (CFET) having nMOS and pMOS transistors vertically stacked. Further, the GAA devices may have one or more channel regions associated with a single, contiguous gate structure, or multiple gate structures. One of ordinary skill may recognize other examples of semiconductor devices that may benefit from aspects of the present disclosure. For example, other types of metal-oxide semiconductor field effect transistors (MOSFETs), such as planar MOSFETs, FinFETs, other multi-gate FETs may benefit from the present disclosure.

Furthermore, the disclosed device structure includes one or more backside contact formed on backside of the substrate and further includes one or more self-protective insulator (SPI), which is formed on bottom of the substrate and is underlying the vertically stacked channels such that the backside contact can be properly landing on the corresponding S/D feature without short issues to the gate electrode even the overlay shift causes misalignment. The GAA devices and methods of manufacture that are proposed in the present disclosure exhibit desirable properties, examples being: (1) a process using dummy interposer or dummy oxide interposer (DOI); (2) various isolation features to eliminate or reduce leakage; and (3) enhanced process flow to reduce shortness and other defects.

In the illustrated embodiments, the IC device includes a GAA device 100. The GAA device 100 may be fabricated during processing of the IC, or a portion thereof, that may include static random access memory (SRAM) and/or logic circuits, passive components such as resistors, capacitors, and inductors, and active components such as p-type field effect transistors (pFETs), n-type FETs (nFETs), FinFETs, MOSFETs, CMOS, bipolar transistors, high voltage transistors, high frequency transistors, other memory cells, and combinations thereof.

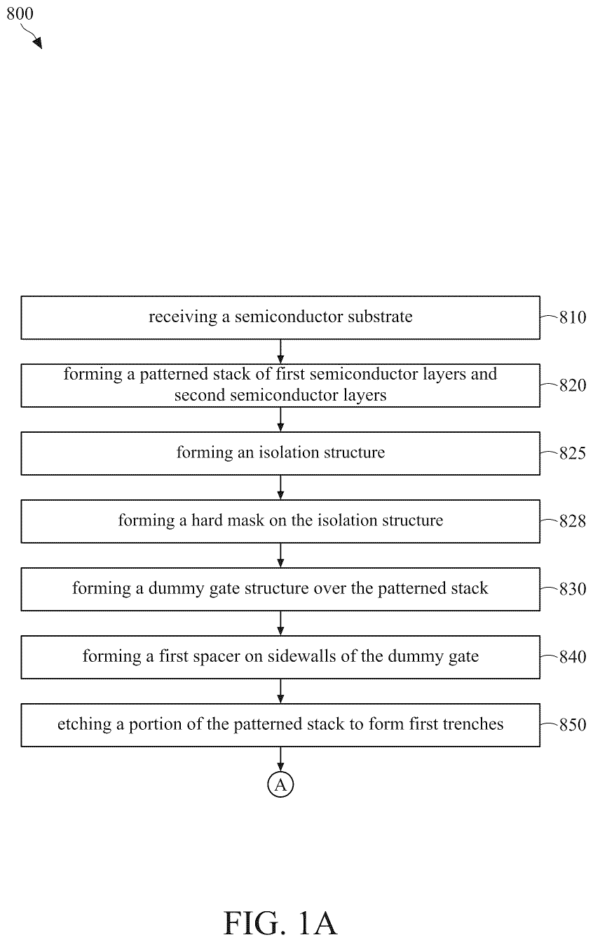

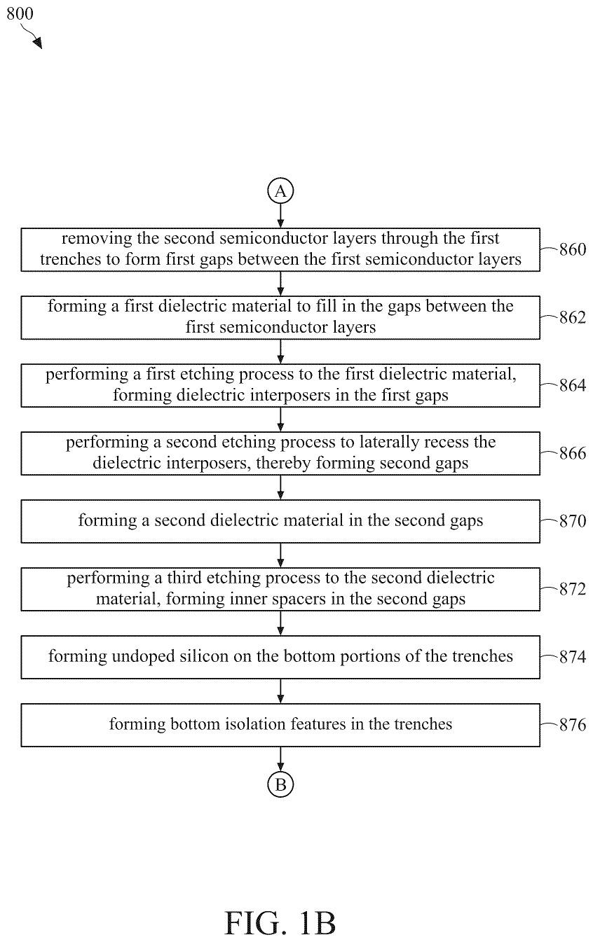

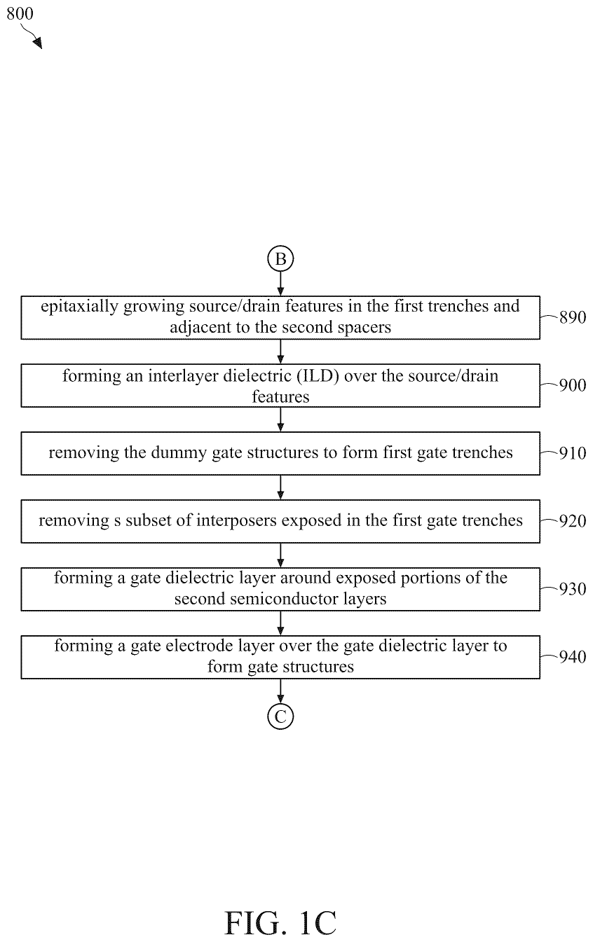

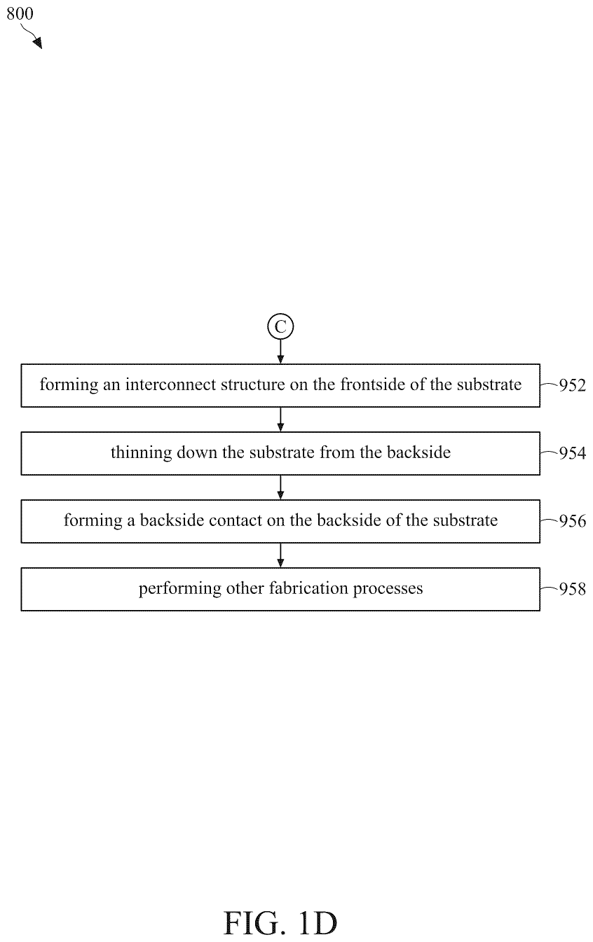

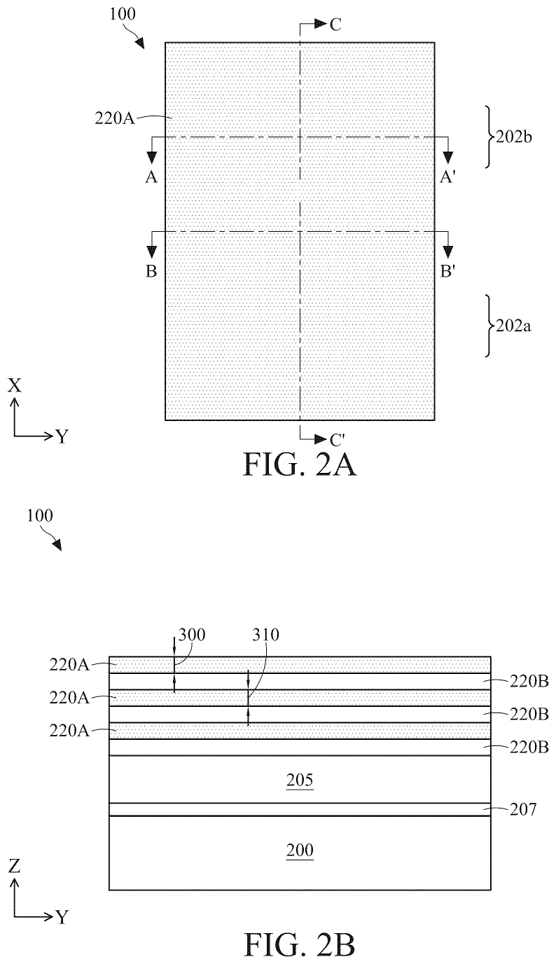

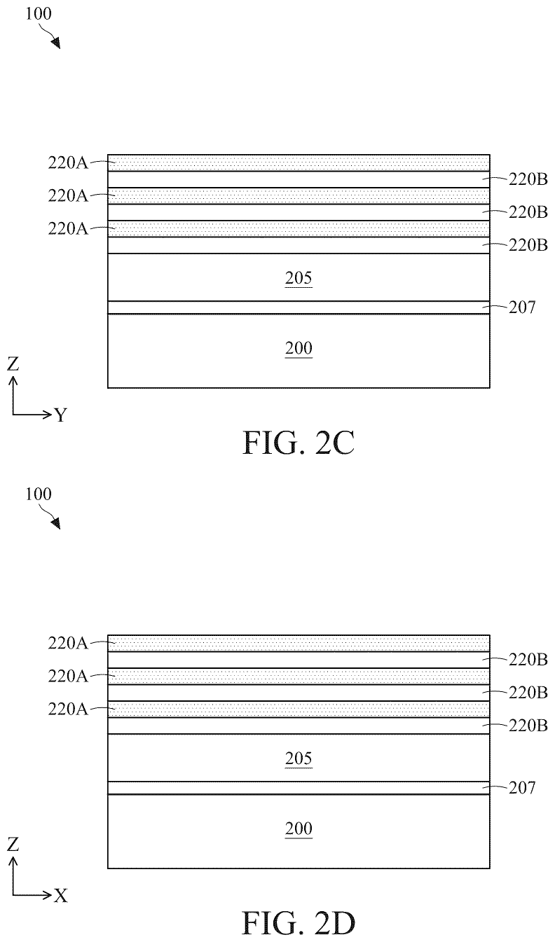

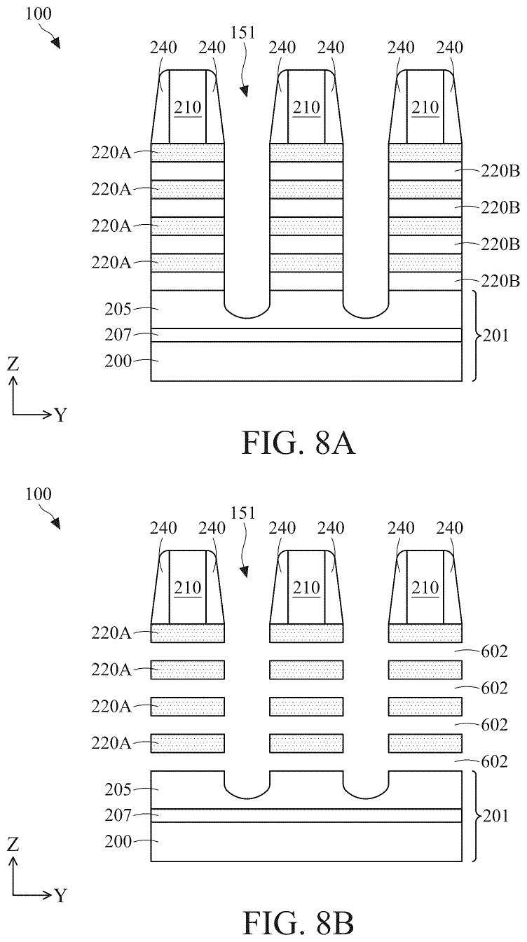

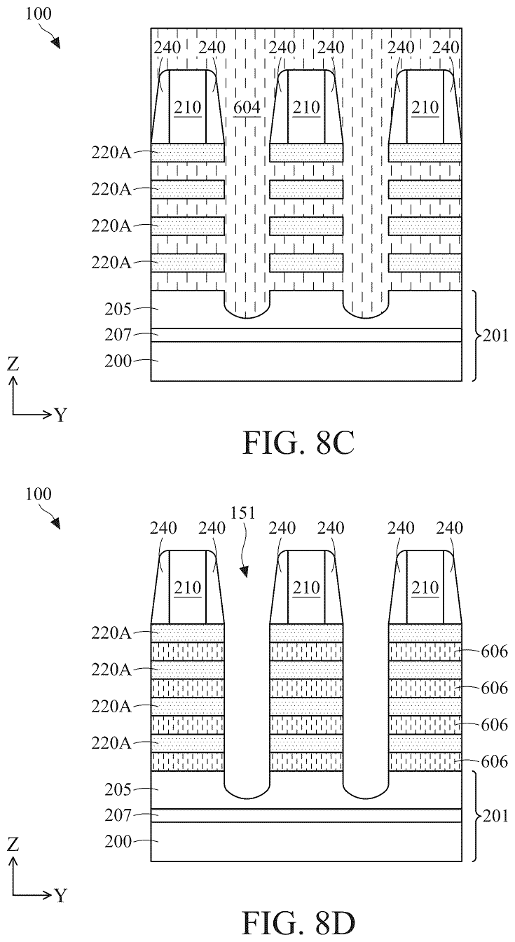

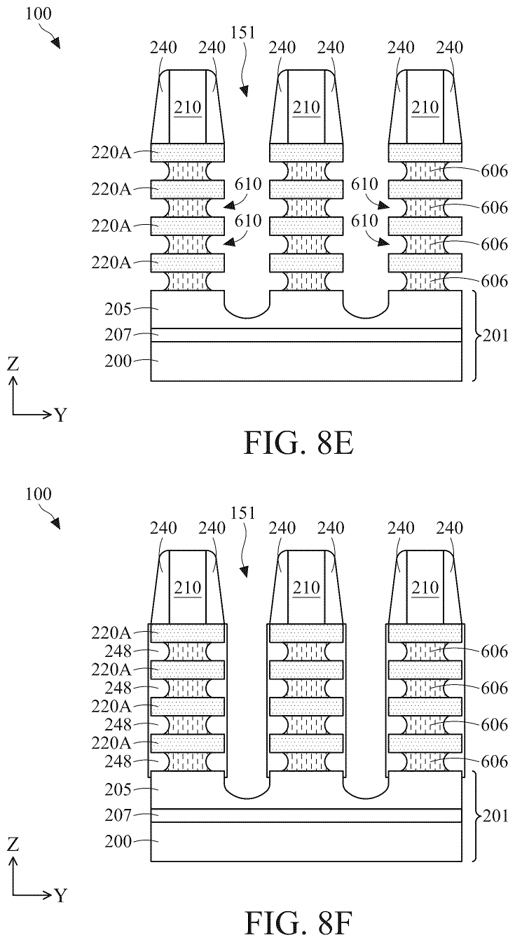

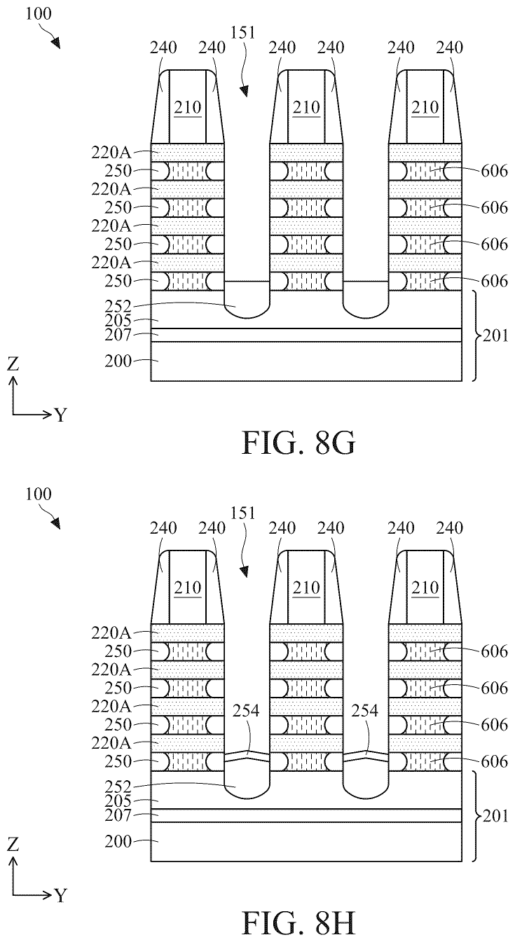

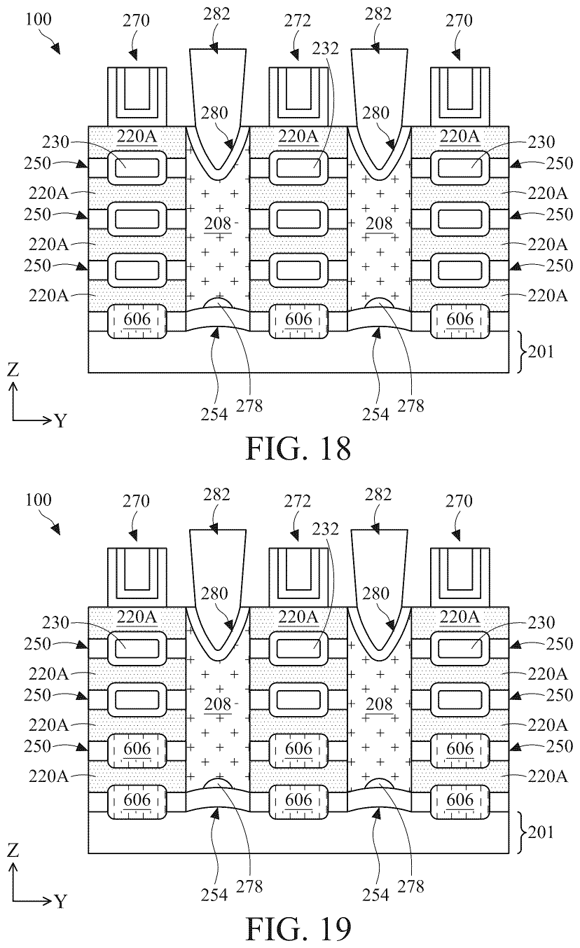

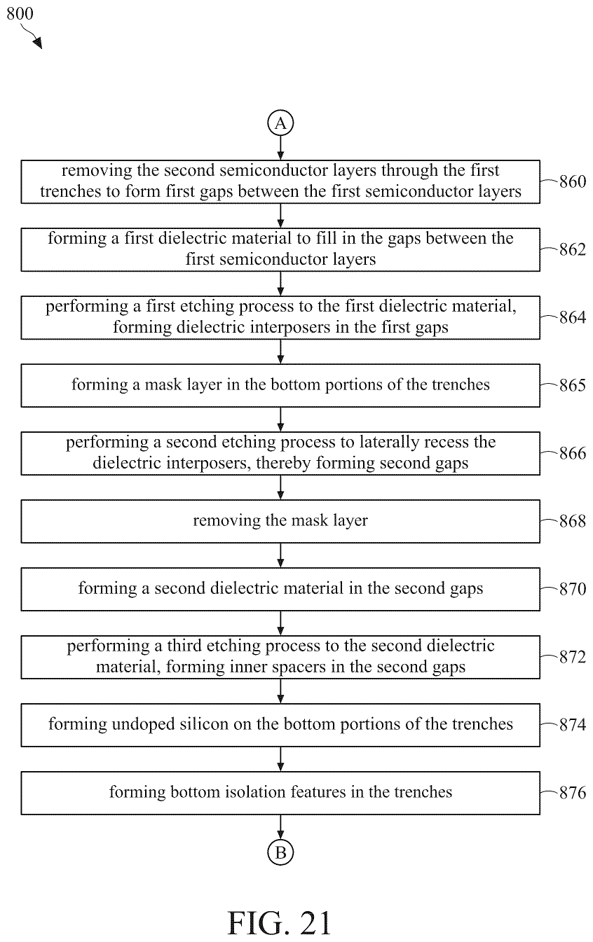

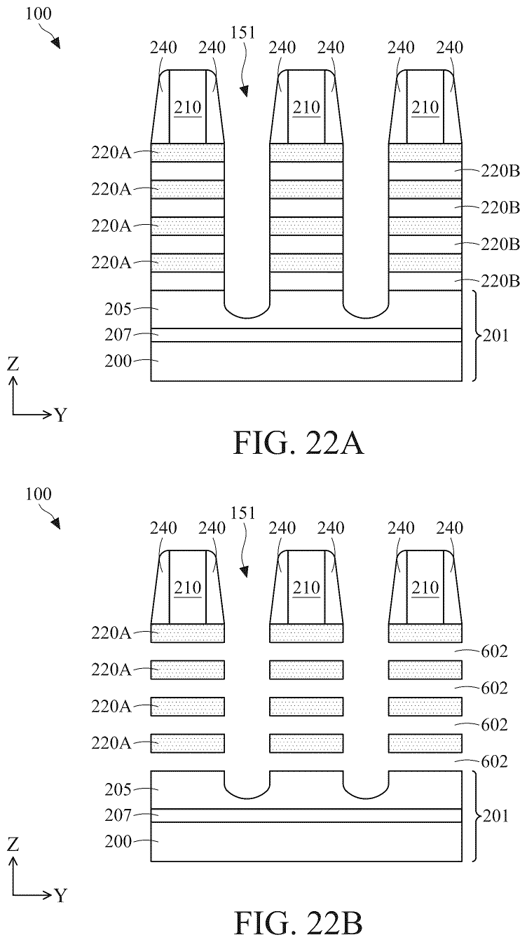

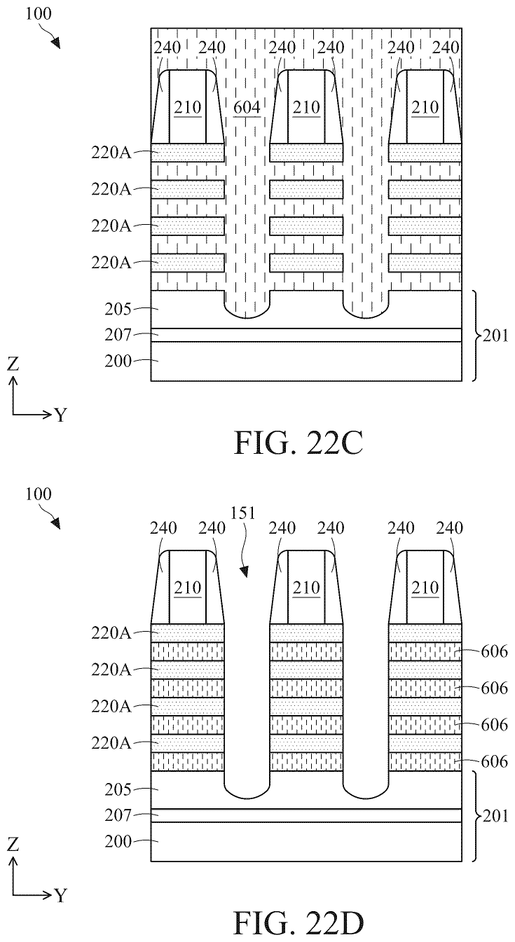

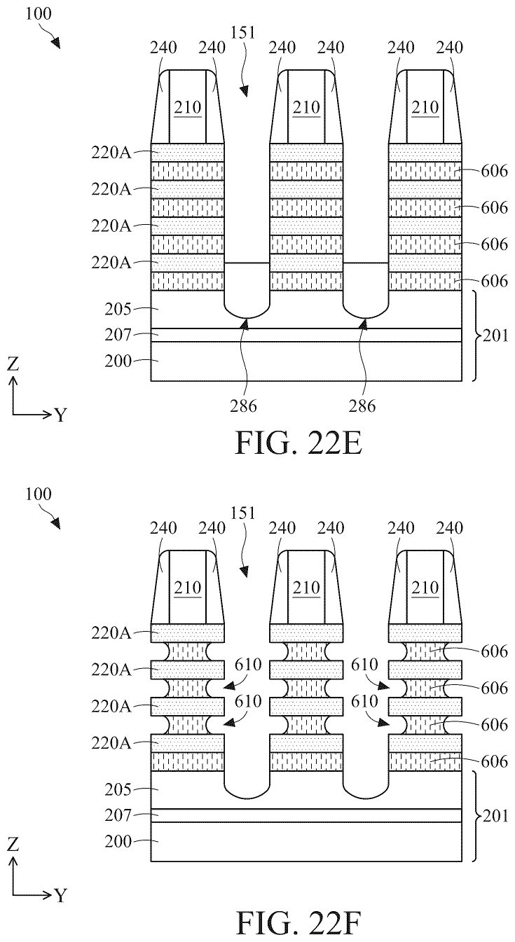

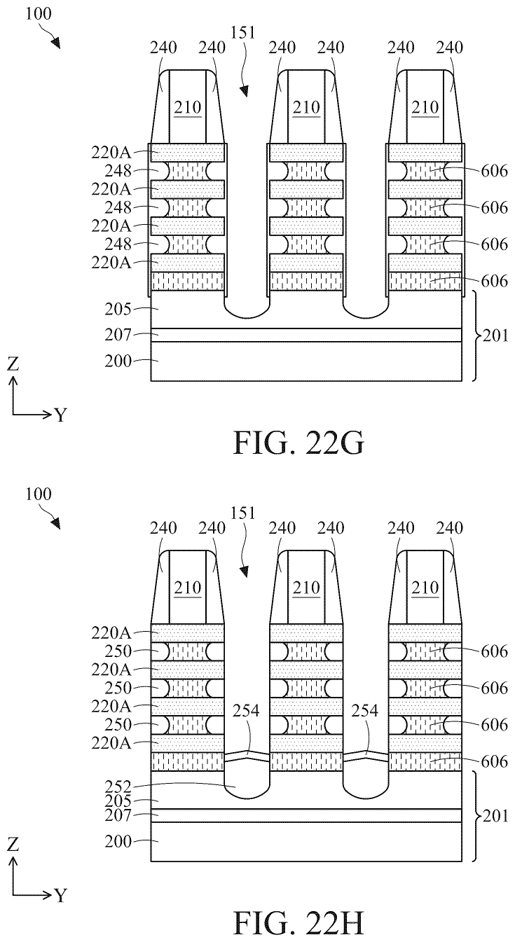

FIGS. 1A-1D are flowcharts of an example method for fabricating an integrated structure (or a GAA device) according to some embodiments of the present disclosure. FIGS. 2A to 7A. 9A to 17A and 24A to 25A are top views of a GAA device of the present disclosure constructed at various fabrication stages according to some embodiments of the present disclosure. FIGS. 2B to 7B, 9B to 17B and 24A to 25A, FIGS. 2C to 7C, 9C to 17C and 24C to 25C, FIGS. 2D to 7D, 9D to 17D and 24D to 25D are cross sectional views a GAA device of the present disclosure along the lines A-A′, B-B′, and C-C′ in FIGS. 2A to 7A. 9A to 17A and 24A to 25A, respectively, according to some embodiments of the present disclosure. FIGS. 8A to 8H are cross-sectional views of example methods for fabricating a GAA device according to some embodiments of the present disclosure. FIGS. 22A to 22H are cross-sectional views of example methods for fabricating a GAA device according to some embodiments of the present disclosure. FIGS. 18 to 20 and 23 are cross sectional views of GAA devices of the present disclosure constructed at according to some embodiments of the present disclosure. FIG. 21 is a flow chart of an example method for fabricating an embodiment of a GAA device according to some embodiments of the present disclosure

Referring to block 810 of FIG. 1A and FIGS. 2A-2D, the GAA device 100 includes a substrate 200. In some embodiments, the substrate 200 contains a semiconductor material, such as bulk silicon (Si). Alternatively or additionally, another elementary semiconductor, such as germanium (Ge) in a crystalline structure, may also be included in the substrate 200. The substrate 200 may also include a compound semiconductor, such as silicon germanium (SiGe), silicon carbide (SiC), gallium arsenic (GaAs), gallium phosphide (GaP), indium phosphide (InP), indium arsenide (InAs), and/or indium antimonide (InSb), or combinations thereof. The substrate 200 may also include a semiconductor-on-insulator substrate, such as Si-on-insulator (SOI), SiGe-on-insulator (SGOI), Ge-on-insulator (GOI) substrates. Portions of the substrate 200 may be doped, such as the doped portions 205. The doped portions 205 may be doped with p-type dopants, such as boron (B) or boron fluoride (BF₃), or doped with n-type dopants, such as phosphorus (P) or arsenic (As). The doped portions 205 may also be doped with combinations of p-type and n-type dopants (e.g. to form a p-type well and an adjacent n-type well). The doped portions 205 may be formed directly on the substrate 200, in a p-well structure, in an n-well structure, in a dual-well structure, or using a raised structure.

Referring to block 820 of FIG. 1A and FIGS. 2A-2D, a stack of semiconductor layers 220A and 220B are formed over the substrate 200 in an interleaving or alternating fashion, extending vertically (e.g. along the Z-direction) from the substrate 200. For example, a semiconductor layer 220B is disposed over the substrate 200, a semiconductor layer 220A is disposed over the semiconductor layer 220B, another semiconductor layer 220B is disposed over the semiconductor layer 220A, so on and so forth. In the depicted embodiments, there are three layers of semiconductor layers 220A and three layers of semiconductor layers 220B alternating between each other. However, there may be any appropriate number of layers in the stack. For example, there may be 2 to 10 layers of semiconductor layers 220A, alternating with 2 to 10 layers of semiconductor layers 220B in the stack. For convenience, the semiconductor layers 220A and 220B are also referred to as the first semiconductor layers 220A and the second semiconductor layers 220B, respectively. The material compositions of the semiconductor layers 220A and 220B are configured such that they have an etching selectivity in a subsequent etching process. For example, in some embodiments, the semiconductor layers 220A contain silicon (Si), while the semiconductor layers 220B contain silicon germanium (SiGe). In some other embodiments, the semiconductor layers 220B contain Si, while the semiconductor layers 220A contain SiGe. In the depicted embodiment, each of the semiconductor layers 220A has a substantially uniform thickness, depicted in FIG. 2B as the thickness 300, while each of the semiconductor layers 220B has a substantially uniform thickness, depicted in FIG. 2B as the thickness 310.

Furthermore, a semiconductor layer 207 is also formed on the substrate 200 and underlying the stack of semiconductor layers. The semiconductor layer 207 is designed to function as a stop layer during backside process, such as during a chemical mechanical polishing (CMP) process performed on the backside of the substrate 200, which will be further described later. In some embodiments, the semiconductor layer 207 includes silicon germanium. In some embodiments, the semiconductor layer 207 may include other suitable semiconductor material, such as silicon carbide, to effectively function as the etch stop layer. The semiconductor layer 207, the stack of semiconductor layers 220A and 220B, the doped portions 205 are collectively formed in a procedure that includes epitaxial growth and in-situ doping. In some embodiments, the semiconductor layer 207 is epitaxially grown on the substrate 200, the doped portion 205 is epitaxially grown on the semiconductor layer 207, the stack of the semiconductor layers 220A and 220B is epitaxially grown on the doped portion 205.

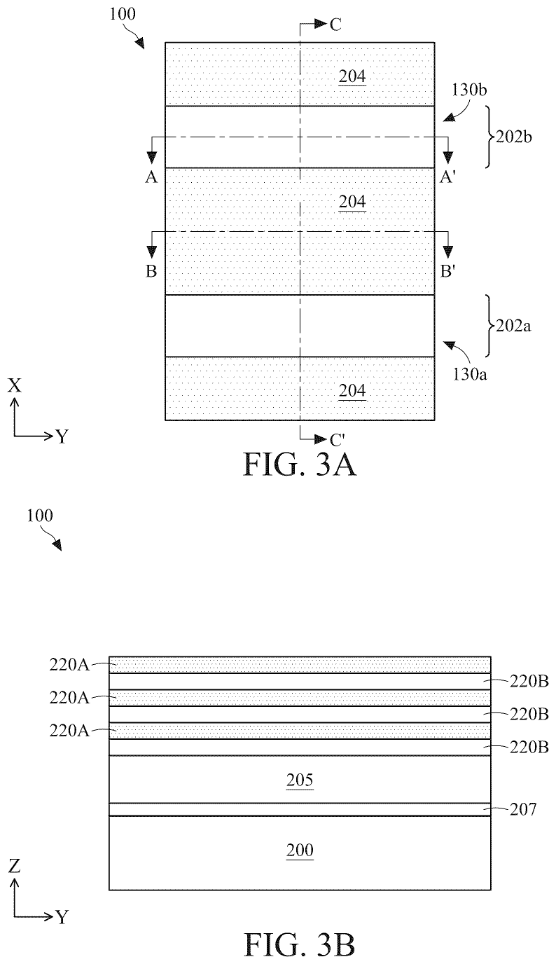

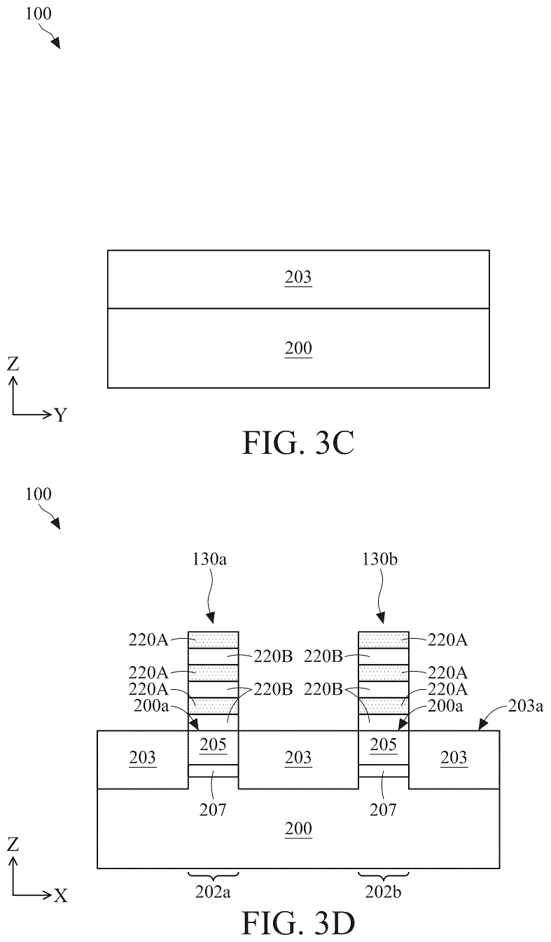

Referring to block 820 of FIG. 1A and FIGS. 3A-3D, the stack of semiconductor layers 220A and 220B are patterned into a plurality of active regions, such as fin structures (or fins) 130a and 130b. The fin structures are active regions protruded above the substrate 200. Each of the fins 130a and 130b includes a stack of the semiconductor layers 220A and 220B disposed in an alternating manner with respect to one another. The fins 130a and 130b each extends lengthwise (e.g. longitudinally) in a first direction (e.g. in the Y-direction) and are separated from each other (e.g. laterally) in a second direction (e.g. in the X-direction), as shown in FIGS. 3A and 3D. As illustrated in FIG. 3A, the fins may each have a lateral width along the X-direction, depicted in FIG. 3A as the width 350. It is understood that the X-direction and the Y-direction are horizontal directions that are perpendicular to each other, and that the Z-direction is a vertical direction that is orthogonal (or normal) to a plane defined by the X-direction and the Y-direction. The substrate 200 may have its top surface aligned in parallel to the XY plane.

The fins 130a and 130b may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins. The patterning may utilize multiple etching processes which may include a dry etching and/or wet etching. The regions in which the fins are formed will be used to form active devices through subsequent processing and are thus referred to as active regions. For example, fin 130a is formed in the active region 202a, and the fin 130b is formed in the active region 202b. Both fins 130a and 130b protrude out of the doped portions 205.

Referring to block 825 of FIG. 1A and FIGS. 3A-3D, the isolation structure 203 is formed on the substrate 200 so that the active regions, such as fins 130a and 130b, are protruded above the top surface of the isolation structure 203. The isolation structure 203 surrounds each of the active regions and isolate the active regions from each other. In some embodiments, the isolation structure 203 includes shallow trench isolation (STI) features (also referred with the numeral 203). In some embodiments, the formation of the isolation structure 203 includes deposition of one or more dielectric material (such as silicon oxide and/or other suitable dielectric material) to fill trenches between active regions; performing a chemical mechanical polishing (CMP) process to planarize the top surface and remove excessive dielectric material deposited on the active regions; and etching to recess the dielectric material. In some examples, the deposited dielectric material includes silicon oxide, silicon nitride, silicon oxynitride, other suitable materials, or combinations thereof. Any appropriate methods, such as a chemical vapor deposition (CVD) process, an atomic layer deposition (ALD) process, a physical vapor deposition (PVD) process, a plasma-enhanced CVD (PECVD) process, a plasma-enhanced ALD (PEALD) process, and/or combinations thereof may be used for depositing the dielectric material of the isolation structure 203. The isolation structure 203 may have a multi-layer structure such as a thermal oxide liner layer over the substrate 200 and a filling layer (e.g., silicon nitride or silicon oxide) over the thermal oxide liner layer. Alternatively, the isolation structure 203 may be formed using any other isolation formation techniques. As illustrated in FIG. 3D, the fins 130a and 130b are located above the top surface 203a of the isolation features 203 (e.g. protrude out of the isolation features 203) and are also located above the top surface 200a of the substrate 200. In some embodiments, the fins 130a/130b and the isolation features 203 are collectively formed in a same procedure, such as a procedure that includes patterning the stack of semiconductor layers 220A and 220B to from fins and trenches; filling the trenches with one or more dielectric materials; performing a chemical mechanical polishing (CMP) process; and etching back the isolation features 203 such that the isolation features 203 are recessed below the fins 130a and 130b.

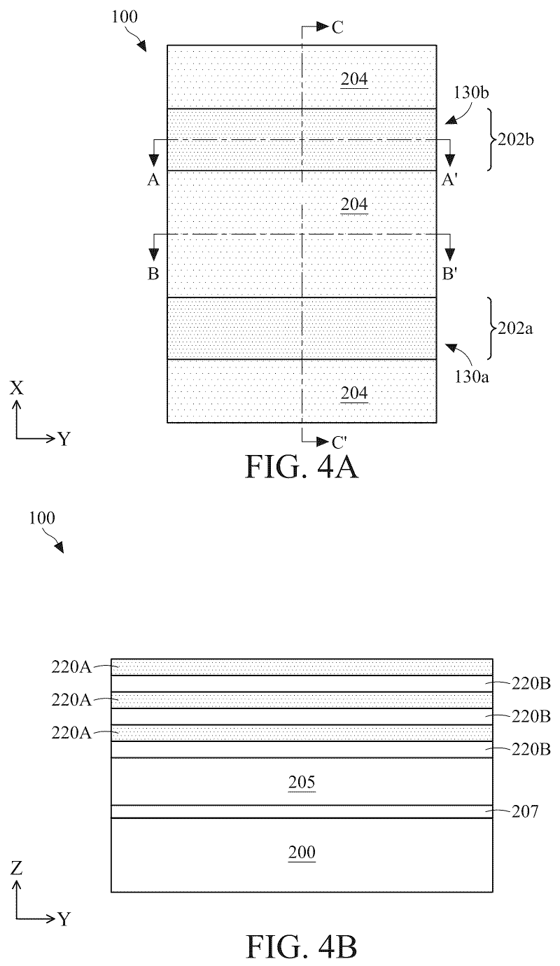

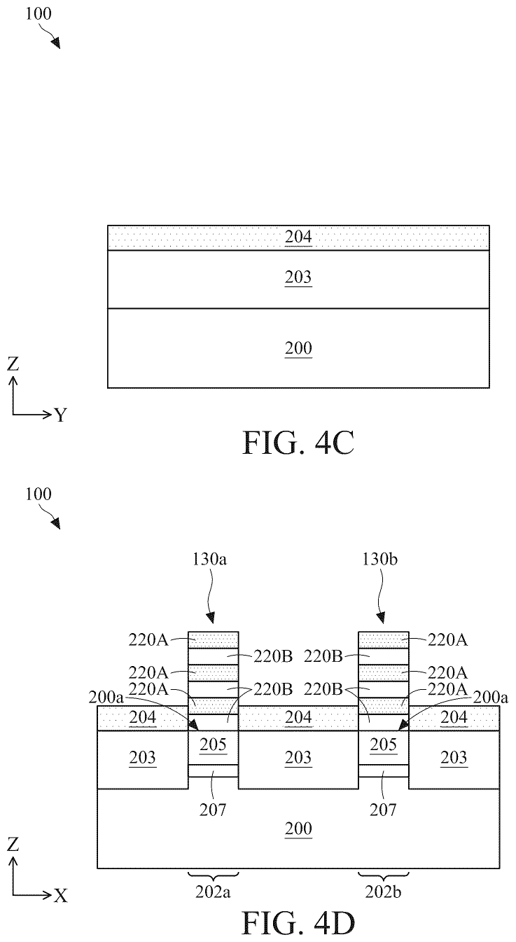

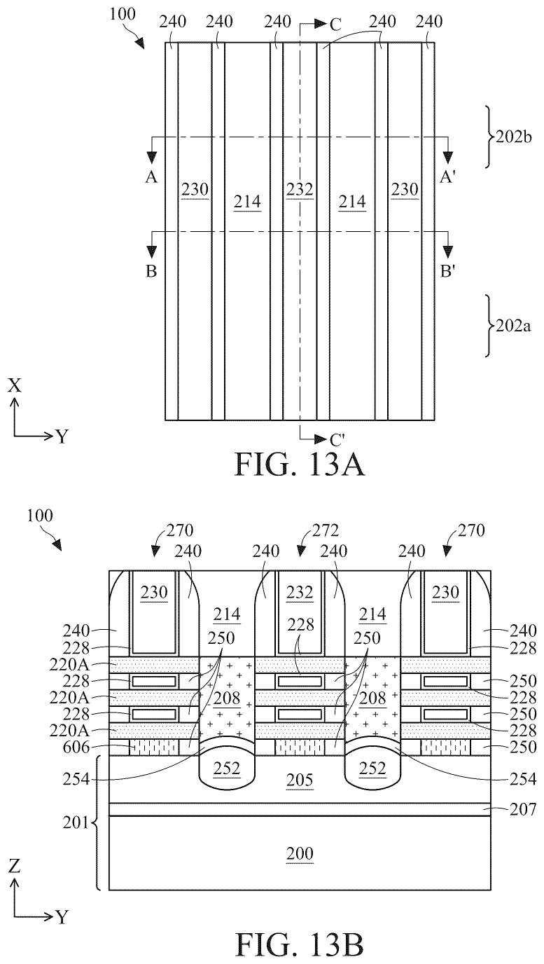

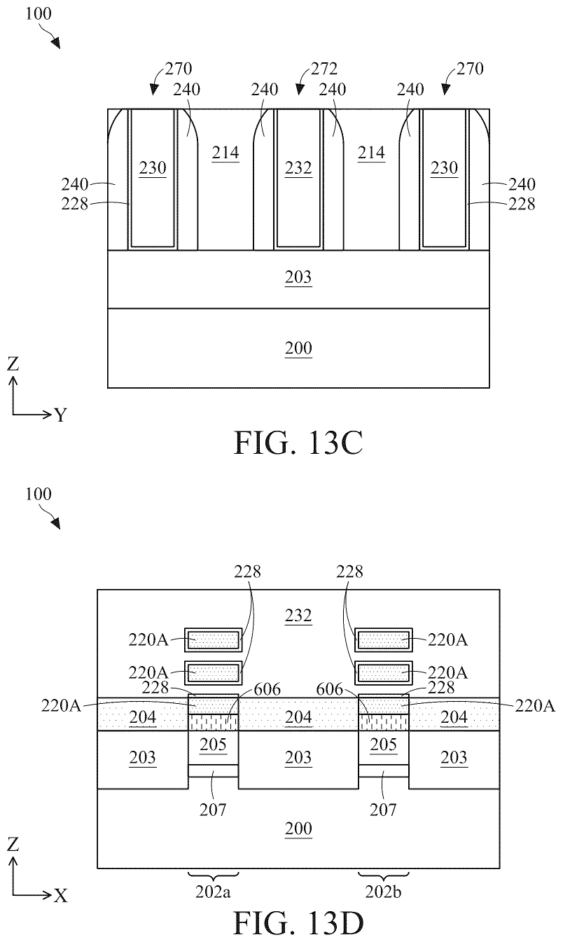

Referring to block 828 of FIG. 1A and FIGS. 4A-4D, a hard mask 204 is formed on the isolation structure 203. The hard mask 204 is also referred to as STI hard mask 204 since the hard mask 204 is formed on the STI features 203. The hard mask 204 is formed on and aligned with the STI features 203 with enough thickness. In the present embodiment, the top surface of the hard mask 204 is above the top surface of the bottommost semiconductor layer 220B such that the bottommost semiconductor layer 220B is embedded in the hard mask 204. In some embodiments, the top surface of the hard mask 204 is above the same level of the top surface of the bottommost semiconductor layer 220B but sidewalls of the bottommost semiconductor layer 220B are fully covered by the hard mask 204, such as those illustrated FIGS. 13D through 17D. The purpose of the hard mask 204 is to form self-protecting isolation (SPI) features in the place of the bottommost semiconductor layer 220B, which will be further described later. In some embodiments, if more than one layer of SPI features to be formed, the thickness of the hard mask 204 is further increased. For example, if two layers of SPI features to be formed, the hard mask 204 has a thickness such that the bottommost two semiconductor layers 220B are embedded in the hard mask 204.

The hard mask 204 includes one or more materials, such as one or more dielectric materials different from that of the isolation structure 203 to achieve etch selectivity. In some embodiments, the isolation structure 203 includes silicon oxide and the hard mask 204 includes silicon nitride. In some embodiments, the isolation structure 203 includes silicon oxide and the hard mask 204 includes silicon nitride, silicon carbide, silicon oxynitride, other different materials or a combination thereof.

The hard mask 204 may be formed by any suitable method. In some embodiments, the hard mask 204 is formed by a method like the formation of the STI features 203. In furtherance of the embodiments, the method includes deposition of one or more dielectric material to the STI features 203, thereby filling the dielectric material in the trenches between the fins; performing a CMP process to the dielectric material; and etching to recess the dielectric material. In other embodiments, the hard mask 204 is formed by a bottom-up deposition process such that the dielectric material is only deposited on the bottom surface of the trenches. In yet other embodiments, the hard mask 204 is formed by a method that includes deposition of the dielectric material; performing a plasma treatment to the deposited dielectric material such that the top portion of the deposited dielectric material is selectively treated with different composition; and performing an etching process to selectively removed the treated dielectric material so that only bottom portion of the deposited dielectric material remains on the STI features 203. In furtherance of the embodiments, the plasma treatment includes a tilted plasma treatment with an angle so that only desired top portion of the dielectric material is treated. In some examples, the plasma treatment includes a plasma of proper species, such as oxygen plasma so that the treated dielectric material converts to silicon oxynitride while untreated dielectric material remains as silicon nitride.

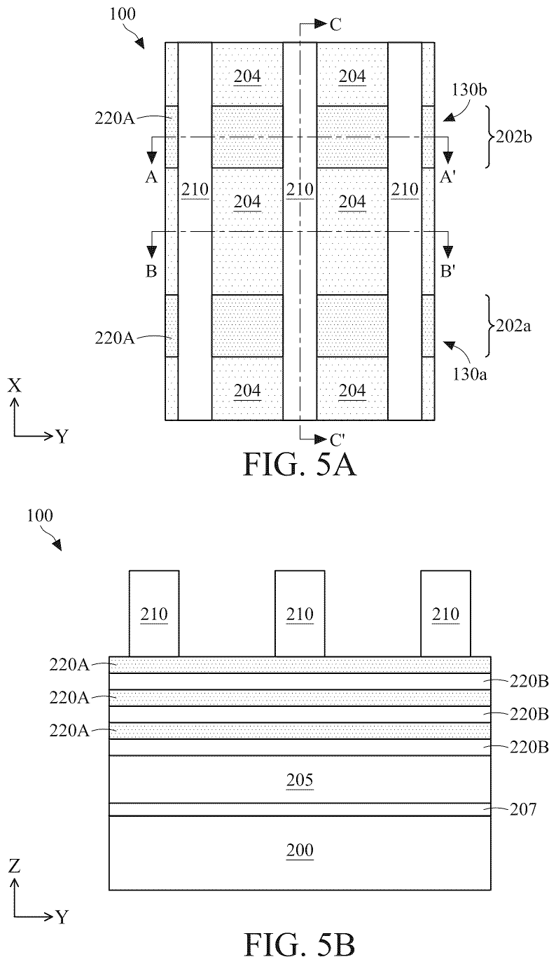

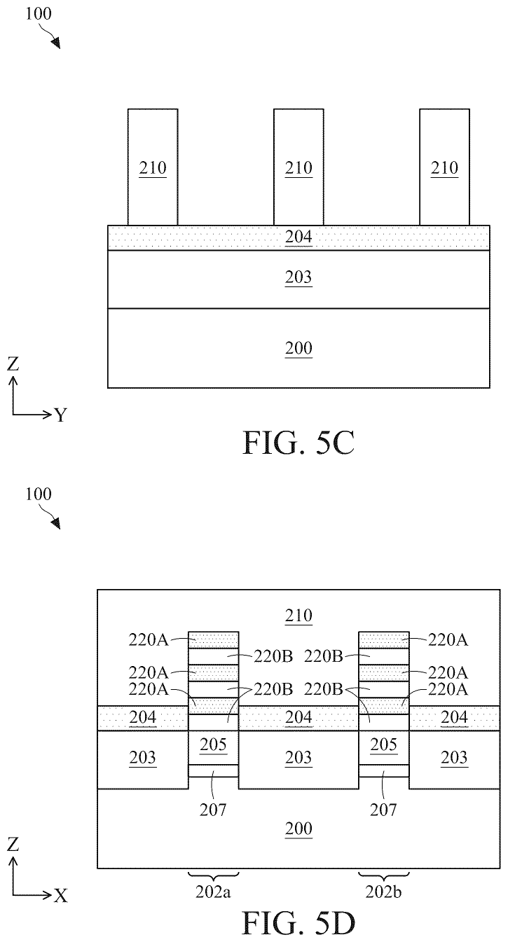

Referring to block 830 of FIG. 1A and FIGS. 5A-5D, dummy gate structures 210 are formed over a portion of each of the fins 130a and 130b, and over the isolation features 203, in between the fins 130a and 130b. The dummy gate structures 210 may be configured to extend lengthwise (e.g. longitudinally) in parallel to each other, for example, each along the X-direction, as shown in FIG. 5A. In some embodiments, as illustrated in FIG. 5D, each of the dummy gate structures wraps around the top surface and side surfaces of each of the fins 130a, 130b. The dummy gate structures 210 may include polysilicon. In some embodiments, the dummy gate structures 210 includes a silicon oxide layer and a polysilicon layer on the silicon oxide layer. In some embodiments, the dummy gate structures 210 may also include one or more mask layers, which are used to pattern the dummy gate electrode layers. The dummy gate structures 210 may undergo a gate replacement process through subsequent processing to form metal gates, such as a high-k metal gate, as discussed in greater detail below. Some of the dummy gate structures 210 may also undergo a second gate replacement process to form a dielectric based gate that electrically isolates the GAA device 100 from neighboring devices, as also discussed in greater detail below. The dummy gate structures 210 may be formed by a procedure including deposition, lithography patterning, and etching processes. The deposition processes may include CVD, ALD, PVD, other suitable methods, and/or combinations thereof.

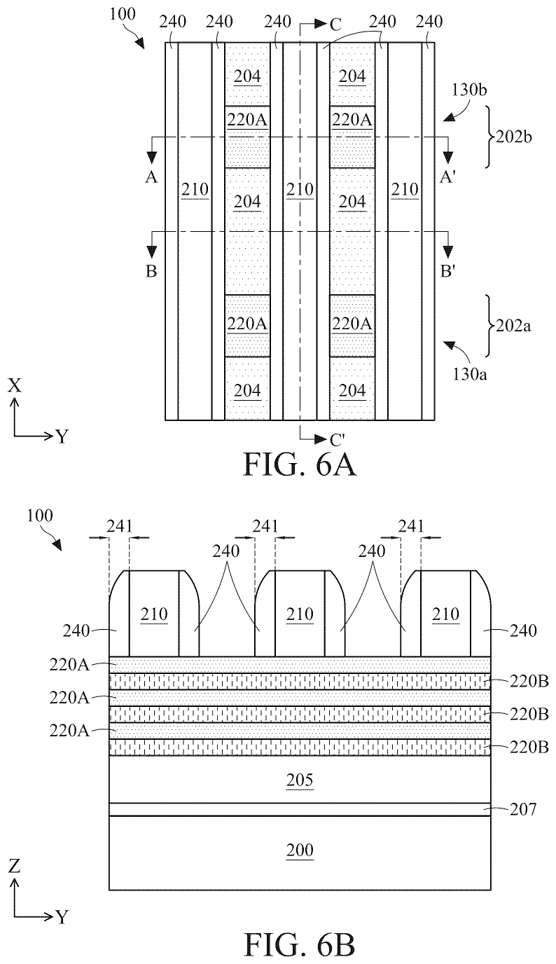

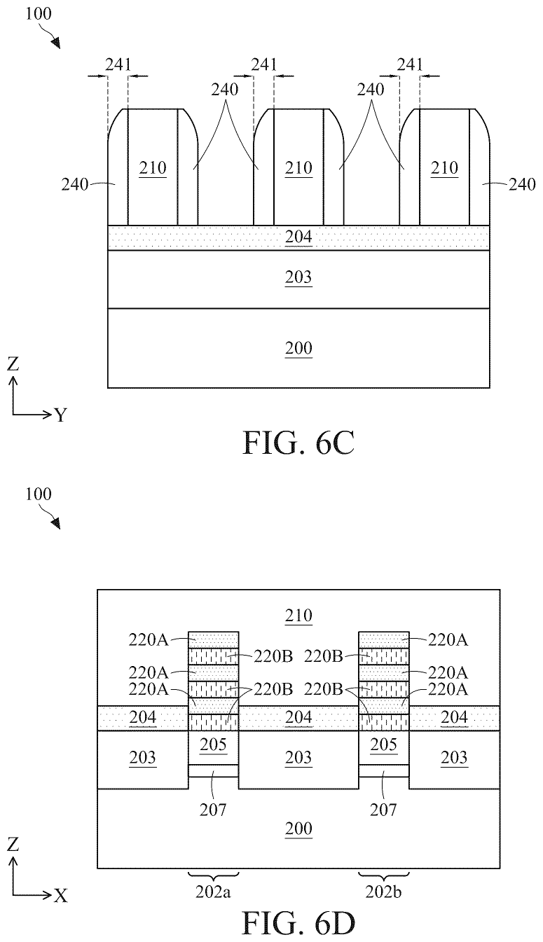

Referring to block 840 of FIG. 1A and FIGS. 6A-6D, gate spacers 240 are formed on the sidewalls of the dummy gate structures 210. The gate spacers 240 may include silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, other suitable dielectric material, or combinations thereof. The gate spacers 240 may include a single layer or a multi-layer structure. In some embodiments, each of the gate spacers 240 may have a thickness 241 (e.g. measured in the Y-direction) in a range from about 3 nm to about 10 nm. A thickness within the stated range of values may be needed for device performance, especially for advanced technology nodes. In some embodiments, the gate spacers 240 may be formed by depositing a spacer layer (containing the dielectric material) over the dummy gate structures 210, followed by an anisotropic etching process to remove portions of the spacer layer from the top surfaces of the dummy gate structures 210. After the etching process, portions of the spacer layer on the sidewall surfaces of the dummy gate structures 210 substantially remain and become the gate spacers 240. In some embodiments, the anisotropic etching process is a dry (e.g. plasma) etching process. Additionally, or alternatively, the formation of the gate spacers 240 may also involve chemical oxidation, thermal oxidation, ALD, CVD, and/or other suitable methods. In the active regions, the gate spacers 240 are formed over the top layer of the semiconductor layers 220A. Accordingly, the gate spacers 240 may also be interchangeably referred to as the top spacers 240. In some examples, one or more material layers (not shown) may also be formed between the dummy gate structures 210 and the corresponding top spacers 240. The one or more material layers may include an interfacial layer and/or a high-k dielectric layer, as examples.

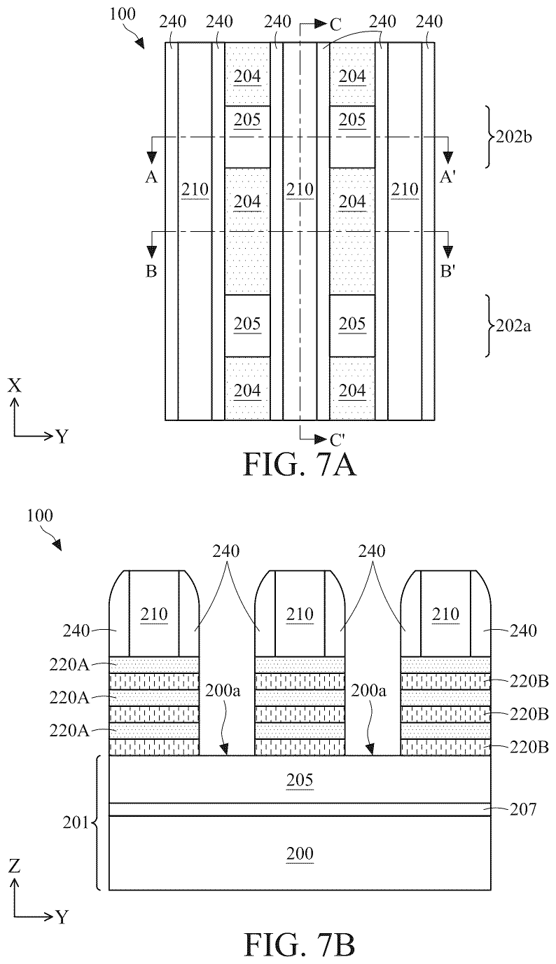

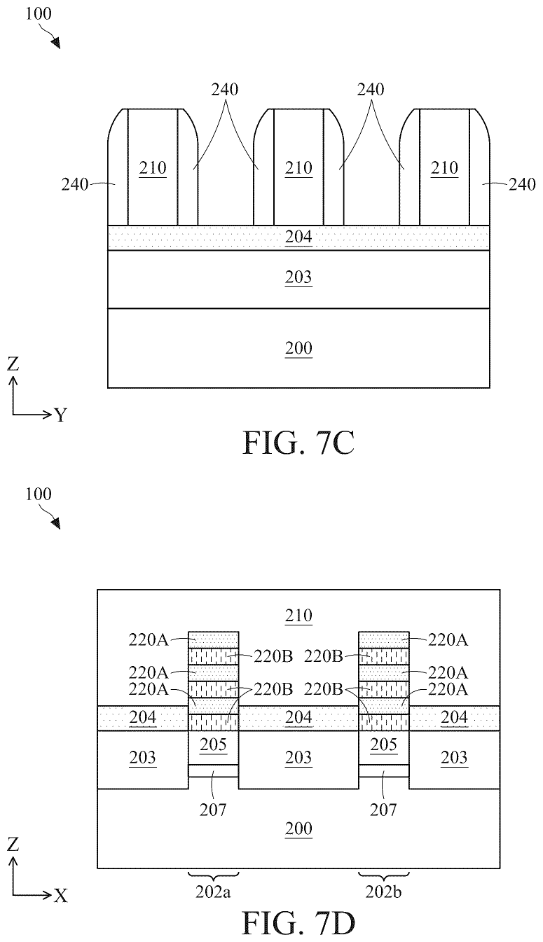

Referring to block 850 of FIG. 1A and FIGS. 7A-7D, source/drain (S/D) portions of the fins 130a and 130b exposed by the dummy gate structures 210 and the gate spacers 240 are at least partially recessed (or etched away) to form trenches 151 for subsequent epitaxial source and drain growth. The process used to form the trenches 151 may include one or multiple lithography and etching steps, and may use any suitable methods, such as dry etching and/or wet etching. As an example, one or more of the multiple lithography and etching steps used to form the trenches 151 may include a first etch process having a first etch chemistry and a second etch process having a second etch chemistry that is different from the first etch chemistry. The first etch process may be a main-etch process that initially forms an opening in the stack of semiconductor layers 220A and 220B, while the second etch process may be an over-etch process that shapes the initially-formed opening to produce the tapered profile observed in the trenches 151. The first etch chemistry may include hydrogen bromide (HBr) combined with argon (Ar), helium (He), oxygen (O₂), or a combination thereof. The second etch chemistry may include hydrogen bromide (HBr) combined with nitrogen, methane (CH₄), or a combination thereof. The second etch process (e.g. the over-etch process) may be performed at a high bias power (e.g. a bias power in a range from about 150 Watts to about 600 Watts).

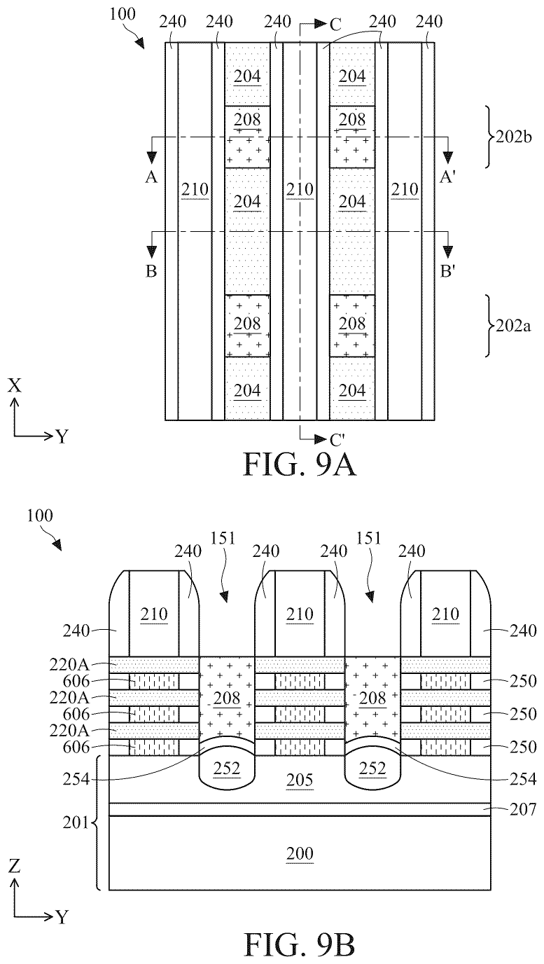

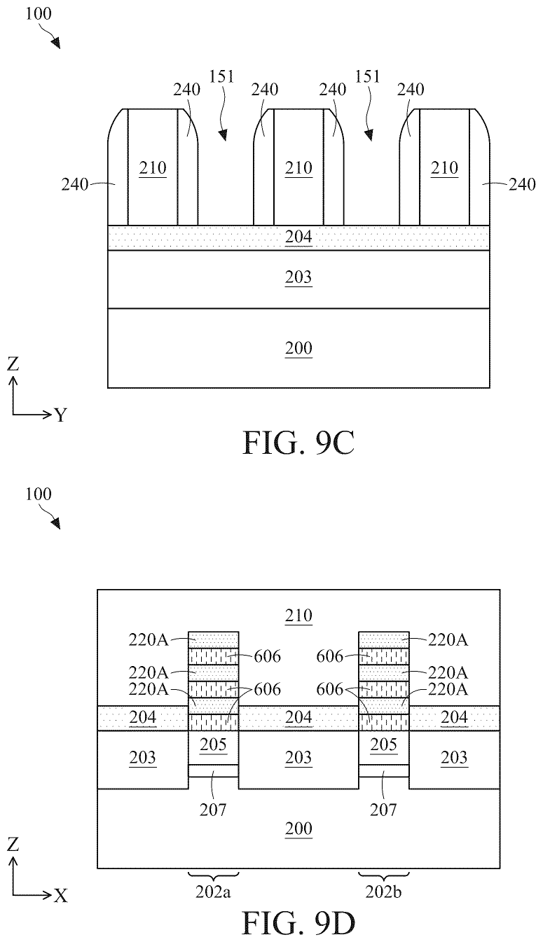

The method 800 proceeds to operations 860 through 876 in FIGS. 8A through 8H, which are associated with processing steps applied in the trenches 151 and designed to reduce the residues and enhance the channel performance. Only FIGS. 8A through 8H in sectional views along AA′ are illustrated for simplicity. Especially, the operations 860 through 876 begin with FIG. 8A, which is similar to FIG. 7B, although the number of the semiconductor layers 220A and the number of the semiconductor layers 220B may be shown differently. As noted above, there may be any appropriate number of layers in the stack. Furthermore, the substrate 200, the semiconductor layers 205 and 207 (sometimes only 205 and 207) shown in FIGS. 8A-8H and following figures (such as, FIGS. 9B-17B, 18-20, 22A-22H, 23 and 24B-25B) are also collectively referred by the numeral 201. FIG. 8A is a duplicate of FIG. 7B. It is understood that those semiconductor layers and the substrate are present, as illustrated in the previous figures, such as FIGS. 7A-7D.

Referring to block 860 of FIG. 1B and FIG. 8B, the semiconductor layers 220B are removed through the trenches 151 via a selective etching process, resulting in first gaps 602 between the semiconductor layers 220A. The selective etching process may be any suitable processes, such as a wet etching or a dry etching process. In an embodiment, the semiconductor layers 220A includes Si and the semiconductor layers 220B includes SiGe. In such an embodiment, a Standard Clean 1 (SC-1) solution may be used to selectively etch away the SiGe semiconductor layers 220B. For example, the SiGe semiconductor layers 220B may be etched away at a substantially faster rate than the Si semiconductor layers 220A. As a result, the semiconductor layers 220B (e.g. the side portions 220B-side) are removed, while the semiconductor layers 220A remain substantially unchanged. The SC-1 solution includes ammonia hydroxide (NH₄OH), hydrogen peroxide (H₂O₂), and water (H₂O). The optimal condition may be reached by additionally adjusting the etching temperature, dopant concentration, as well as other experimental parameters.

In another embodiment, the semiconductor layers 220A include SiGe and the semiconductor layers 220B includes Si. In such an embodiment, a cryogenic deep reactive ion etching (DRIE) process may be used to selectively etch away the Si semiconductor layer 220B. For example, the DRIE process may implement a sulfur hexafluoride-oxygen (SF₆—O₂) plasma. The optimal condition may be reached by adjusting the etching temperature, the power of the Inductively Coupled Plasma (ICP) power source and/or Radio Frequency (RF) power source, the ratio between the SF₆ concentration and the O₂ concentration, the dopant (such as boron) concentrations, as well as other experimental parameters. For example, the etching rate of a Si semiconductor layer 220B using a SF₆—O₂ plasma (with approximately 6% O₂) may exceed about 8 μm/min at a temperature of about −80° C.; while the SiGe semiconductor layers 220A are not substantially affected during the process.

Referring to block 862 of FIG. 1B and FIG. 8C, one or more dielectric material 604 is deposited to fill in the first gaps 602. The dielectric material 604 is deposited on sidewalls of the trenches 151, the sidewalls of the gate spacers 240 and the top of the gate structures 210. The dielectric material 604 may include silicon oxide, silicon nitride, silicon oxynitride, any suitable dielectric material, or a combination thereof.

In some embodiments, the gate spacers 240 includes silicon oxide. The dielectric material of silicon oxide may be formed by CVD, low pressure chemical vapor deposition (LPCVD), atmospheric pressure chemical vapor deposition (APCVD), flowable CVD (FCVD), thermal oxidation, other suitable method, or a combination thereof.

In some examples, silicon oxide is formed by CVD using a precursor including silane (SiH4) and oxygen (O2), alternatively further including PH3 or B2H6 as dopants. The deposition temperature ranges between 400° C. and 500° C. In some examples, silicon oxide is formed by LPCVD using a precursor including tetraethoxysilane Si(OC2H5)4 (TEOS) and oxygen (O2) with a deposition temperature around 700° C, such as in a range between 650° C. and 750° C. In some examples, silicon oxide is formed by PECVD using a precursor including TEOS and ozone (O3) with a deposition temperature ranging between 300° C. and 350° C. In some examples, silicon oxide is formed by PECVD using a precursor including SiH4 and N2O with a deposition temperature ranging between 200° C. and 450° C. In some examples, silicon oxide is formed by APCVD using a precursor including TEOS and O3 with a deposition temperature ranging between 350° C. and 500° C. In some examples, silicon oxide is formed by thermal oxidation PECVD using a precursor including SiH4 and N2O with a deposition temperature ranging between 200° C. and 450° C.

In the disclosed embodiment, the dielectric layer 604 includes silicon oxide and is formed by a procedure that includes CVD and FCVD. For example, a CVD is applied to form a thin silicon oxide layer, and FCVD is applied thereafter to form another silicon oxide completely fill the first gaps 602. In furtherance of the embodiment, the first deposition step includes forming a first silicon oxide layer by CVD using a precursor including silane (SiH4) and oxygen (O2) with a deposition temperature ranging between 400° C. and 500° C.; and the second deposition step includes forming a second silicon oxide layer by FCVD with details described below. The FCVD process may include the deposition of a silicon-and-nitrogen containing film (e.g., a silicon-nitrogen-hydrogen (Si—N—H) film) from a carbon-free silicon-and-nitrogen precursor and radical precursor. Because the silicon-and-nitrogen film is formed without carbon, the conversion of the film into hardened silicon oxide is done with less pore formation and less volume shrinkage. The conversion of the silicon-and-nitrogen film to silicon oxide may be done by heating the silicon-and-nitrogen film in an oxygen-containing atmosphere. The oxygen-containing gases in this atmosphere may include radical atomic oxygen (O), molecular oxygen (O2), ozone (O3), and/or steam (H2O), among other oxygen-containing gases. The heating temperatures, times, and pressures are sufficient to oxidize the silicon-and-nitrogen film into the silicon oxide film.

Referring to block 864 of FIG. 1B and FIG. 8D, an etching process (also referred to as a first etching process) is applied to the dielectric material 604, thereby removing the portions of the dielectric material 604 deposited on the sidewalls of the trenches 151, resulting in the dielectric interposers (or dummy oxide interposers) 606 in the first gaps 602. The method includes an anisotropic etch, such as a plasma etch, with etch substantially on the vertical direction. In furtherance of the embodiment, the plasma etch includes an etchant having fluorine-containing gas, chlorine-containing gas, other suitable gas or a combination thereof.

Referring to block 866 of FIG. 1B and FIG. 8E, an etching process (also referred to as a second etching process) is applied to the dielectric interposers 606 so that the dielectric interposers 606 are laterally recessed through the exposed sidewall surfaces in the trenches 151 via a selective etching process. The selective etching process may be any suitable etching processes, such as a wet etching or a dry etching process. The extent to which the dielectric interposers 606 are recessed (or the size of the portion removed) is determined by the processing conditions such as the duration the dielectric interposers 606 is exposed to an etching chemical. In the depicted embodiments, the duration is controlled such that the side portions of the dielectric interposers 606 directly underlying the gate spacers 240 are removed in their entirety, while the center portions of the dielectric interposers 606 remain substantially unchanged. In other words, the remaining portions of the dielectric interposers 606 each has a sidewall that is substantially aligned with a sidewall of the dummy gate structures 210 (e.g. the sidewall in the XZ plane, defined by the X-direction and the Z-direction). As illustrated in FIG. 8E, the selective etching process creates recesses (also referred to as second gaps) 610, which extend the trenches 151 into areas beneath the semiconductor layers 220A and top spacers 240. Meanwhile, the semiconductor layers 220A are only slightly affected during the selective etching process. The etch selectivity between the first semiconductor layers 220A and the dielectric interposers 606 is made possible by the etchant and etching process. For example, the dielectric interposers 606 may be etched away at a substantially faster rate (e.g. more than about 5 times to about 10 times faster) than the first semiconductor layers 220A. In some embodiments, the etching process is wet etching with HF solution as etchant.

Referring to block 870 of FIG. 1B and FIG. 8F, a dielectric material 248 is filled in the second gaps 610. The method to form the dielectric material 248 includes deposition using a suitable deposition technology. The dielectric material 248 is different from the composition of the dielectric interposers 606 to achieve etch selectivity during subsequent processes, such as during the channel-release operation. In some embodiments, the dielectric material 248 may be selected from SiON, SiOC, SiOCN, other suitable dielectric material or combinations thereof. In some embodiments, the proper selection of the dielectric material may be based on its dielectric constant. In an embodiment, the dielectric material 248 may have a dielectric constant lower than that of the top spacers 240. In some other embodiments, this dielectric material may have a dielectric constant higher than that of the top spacers 240. This aspect of the dielectric material will be further discussed later. The deposition of the dielectric material may be any suitable methods, such as CVD, PVD, PECVD, MOCVD, ALD, PEALD, or combinations thereof.

Referring to block 872 of FIG. 1B and FIG. 8F, an etching process (also referred to as a third etching process) is applied to the dielectric material 248 such that the dielectric material 248 formed on sidewalls of the trenches 151 is removed by the third etching process. The third etching process includes an anisotropic etch with substantially vertical etching so that the portions of the dielectric material 246 deposited on the sidewalls and bottom surface of the trenches 151 are removed. In the depicted embodiment, the third etching process is a self-aligned anisotropic dry-etching process, such that the top spacers 240 are used as the masking element. Alternatively, a different masking element (e.g. a photoresist) may be used. The third etching process removes the dielectric materials 248 within the trenches 151 but does not substantially affect the dielectric materials 248 within the second gaps 610. As a result, the dielectric material 248 filling the second gaps 610 become inner spacers 250. In other words, the inner spacers 250 are formed in the second gaps 610 between vertically adjacent (e.g. along in the Z-direction) side portions of the first semiconductor layers 220A.

Referring to block 874 of FIG. 1B and FIG. 8G, semiconductor features 252 are formed on the bottom portions of the trenches 151. The semiconductor features 252 are undoped silicon formed by selective epitaxial growth. The semiconductor features 252, as undoped silicon, can provide isolation and avoid short to adjacent active regions.

Referring to block 876 of FIG. 1B and FIG. 8H, bottom isolation features 254 are formed on the bottom portions of the trenches 151. The bottom isolation features 254 are dielectric features to provide isolation of the source/drain features from the substrate 200 and other conductive features, such as backside contacts. In some embodiments, the bottom isolation features 254 include silicon oxide, other suitable dielectric material (such as silicon oxynitride) or a combination thereof. In the present embodiment, the bottom isolation features 254 are formed on the semiconductor features 252. The bottom isolation features 254 and the semiconductor features 252 collectively provide effective isolation function. The bottom isolation features 254 may be formed by any suitable method, such as methods similar to the formation of the hard mask 204.

In some embodiments, the bottom isolation features 254 are formed by a method that includes deposition of one or more dielectric material to the semiconductor features 252, thereby filling the dielectric material in the trenches 151; performing a CMP process to the dielectric material; and etching to recess the dielectric material. In other embodiments, the bottom isolation features 254 is formed by a bottom-up deposition process such that the dielectric material is only deposited on the bottom surface of the trenches, such as on the semiconductor features 252. In yet other embodiments, the bottom isolation features 254 are formed by a method that includes deposition of the dielectric material; performing a plasma treatment to the deposited dielectric material such that the top portion of the deposited dielectric material is selectively treated with different composition; and performing an etching process to selectively removed the treated dielectric material so that only bottom portion of the deposited dielectric material remains on the semiconductor features 252. In furtherance of the embodiments, the plasma treatment includes a tilted plasma treatment with an angle so that only desired top portion of the dielectric material is treated. In some examples, the plasma treatment includes a plasma of proper species, such as oxygen plasma so that the treated dielectric material converts to silicon oxynitride while untreated dielectric material remains as silicon nitride.

The following operations are described with references to FIGS. 9A to 17A in top views and FIGS. 9B to 17B, 9C to 17C, and 9D to 17D sectional views constructed according to various embodiments.

Referring to block 890 of FIG. 1C and FIGS. 9A-9D, the method 800 continues to form epitaxial source/drain features 208 in the trenches 151. In some embodiments, one source/drain feature is a source electrode, and the other source/drain feature is a drain electrode. The semiconductor layers 220A that extend from one source/drain feature 208 to the other source/drain feature 208 may form channels of the GAA device 100. Multiple processes including growth processes may be employed to grow the epitaxial source/drain features 208. In the depicted embodiment, the epitaxial source/drain features 208 have top surfaces that are substantially aligned with the top surface of the topmost semiconductor layer 220A. However, in other embodiments, the epitaxial source/drain features 208 may alternatively have top surfaces that extend higher than the top surface of the topmost semiconductor layer 220A (e.g. in the Z-direction). In the depicted embodiment, the epitaxial source/drain features 208 occupy a lower portion of the trenches 151 (e.g. the portion defined by the inner spacers 250 and the semiconductor layers 220A), leaving an upper portion of the trenches 151 (e.g. the portion defined by the top spacers 240) open. In some embodiments, the epitaxial source/drain features 208 may merge together, for example, along the X-direction, to provide a larger lateral width than an individual epitaxial feature. In the depicted embodiments, as shown in FIG. 9A, the epitaxial source/drain features 208 are not merged.

The epitaxial source/drain features 208 may include any suitable semiconductor materials. For example, the epitaxial source/drain features 208 in an n-type GAA device may include Si, SiC, SiP, SiAs, SiPC, or combinations thereof; while the epitaxial source/drain features 208 in a p-type GAA device may include Si, SiGe, Ge, SiGeC, or combinations thereof. The source/drain features 208 may be doped in-situ or ex-situ. For example, the epitaxially grown Si source/drain features may be doped with carbon to form silicon:carbon (Si:C) source/drain features, phosphorous to form silicon:phosphor (Si:P) source/drain features, or both carbon and phosphorous to form silicon carbon phosphor (SiCP) source/drain features; and the epitaxially grown SiGe source/drain features may be doped with boron. One or more annealing processes may be performed to activate the dopants in the epitaxial source/drain features 208. The annealing processes may include rapid thermal annealing (RTA) and/or laser annealing processes.

The epitaxial source/drain features 208 directly interface with the continuous sidewall surfaces of the first semiconductor layers 220A. During the epitaxial growth, semiconductor materials grow from the exposed top surface 200a of the substrate 200 (e.g. the exposed top surface of doped region 205) as well as from the exposed side surfaces of the semiconductor layers 220A. It is noted that semiconductor materials do not grow from the surfaces of the inner spacers 250 and the top spacers 240 during the epitaxial growth process.

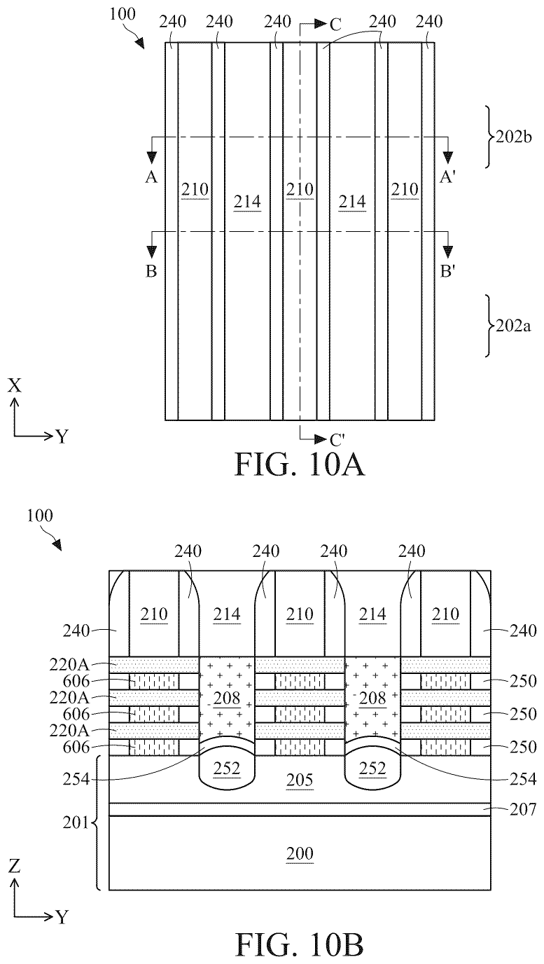

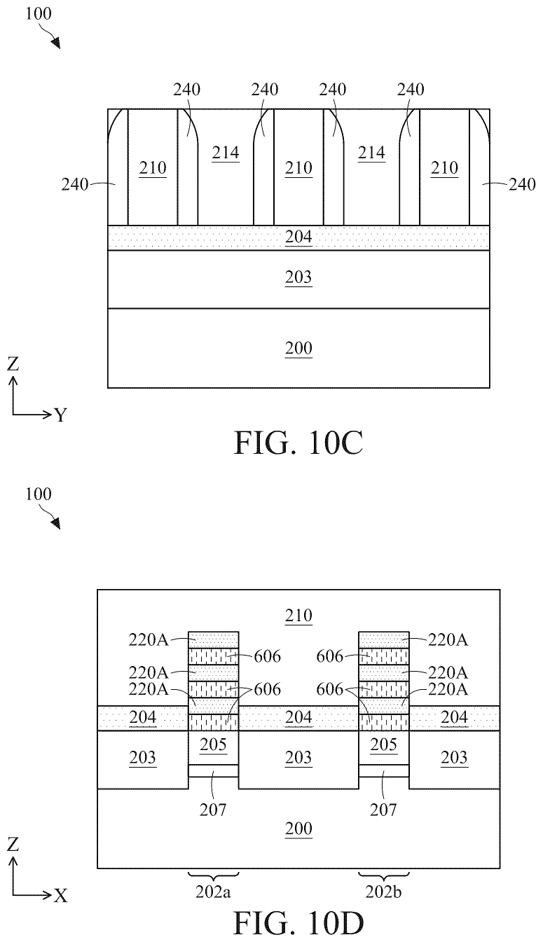

Referring to block 900 of FIG. 1C and FIGS. 10A-10D, an interlayer dielectric (ILD) layer 214 is formed over the epitaxial source/drain features 208 in the remaining spaces of the trenches 151, as well as vertically over the isolation features 203. The ILD layer 214 may also be formed in between the adjacent gates 210 along the Y-direction, and in between the source/drain features 208 along the X-direction. The ILD layer 214 may include a dielectric material, such as a high-k material, a low-k material, or an extreme low-k material. For example, the ILD layer 214 may include SiO₂, SiOC, SiON, or combinations thereof. The ILD layer 214 may include a single layer or multiple layers, and may be formed by a suitable technique, such as CVD, FCVD, and/or spin-on techniques. After forming the ILD layer 214, a CMP process may be performed to remove excessive portions of the ILD layer 214, thereby planarizing the top surface of the ILD layer 214. Among other functions, the ILD layer 214 provides electrical isolation between the various components of the GAA device 100.

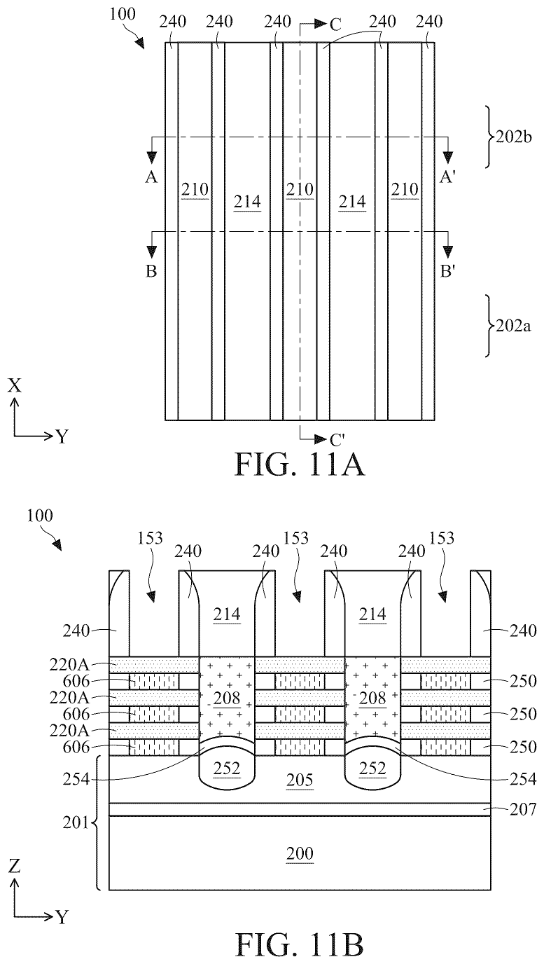

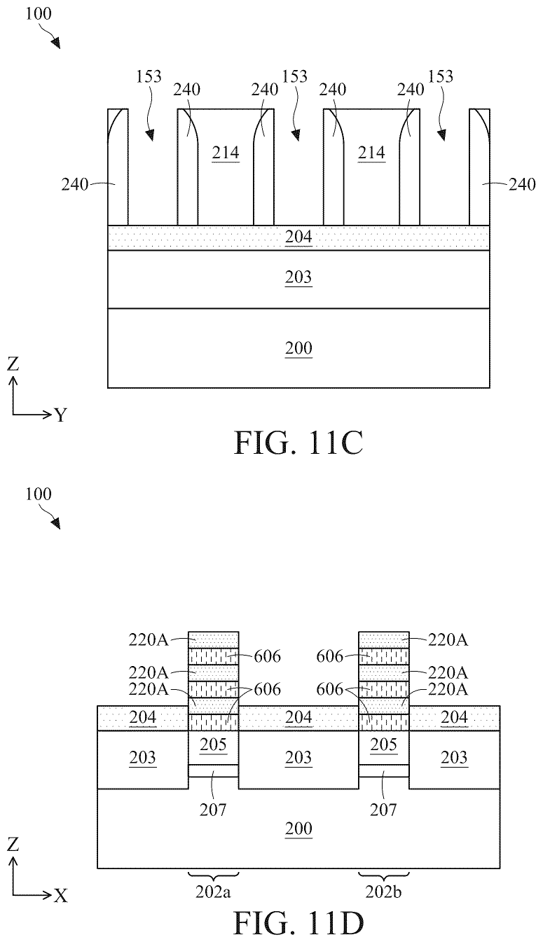

Referring to block 910 of FIG. 1C and FIGS. 11A-11D, the dummy gate structures 210 are selectively removed through any suitable lithography and etching processes. In some embodiments, the lithography process may include forming a photoresist layer (resist), exposing the resist to a pattern, performing a post-exposure bake process, and developing the resist to form a masking element, which exposes a region including the dummy gate structures 210. Then, the dummy gate structures 210 are selectively etched through the masking element. In some other embodiments, the top spacers 240 may be used as the masking element or a part thereof. For example, the dummy gate structures 210 may include polysilicon, the top spacers 240 and the inner spacers 250 may include dielectric materials, and the semiconductor layers 220A includes a semiconductor material. Therefore, an etch selectivity may be achieved by selecting appropriate etching chemicals, such that the dummy gate structures 210 may be removed without substantially affecting the features of the GAA device 100. The removal of the dummy gate structures 210 creates gate trenches 153. The gate trenches 153 expose the top surfaces and the side surfaces of the first semiconductor layers 220A, and the dielectric interposers 606, as depicted in FIG. 10D. In other words, the first semiconductor layers 220A and the dielectric interposers 606 are exposed at least on two side surfaces in the gate trenches 153. Additionally, the gate trenches 153 also expose the top surfaces of the isolation features 203.

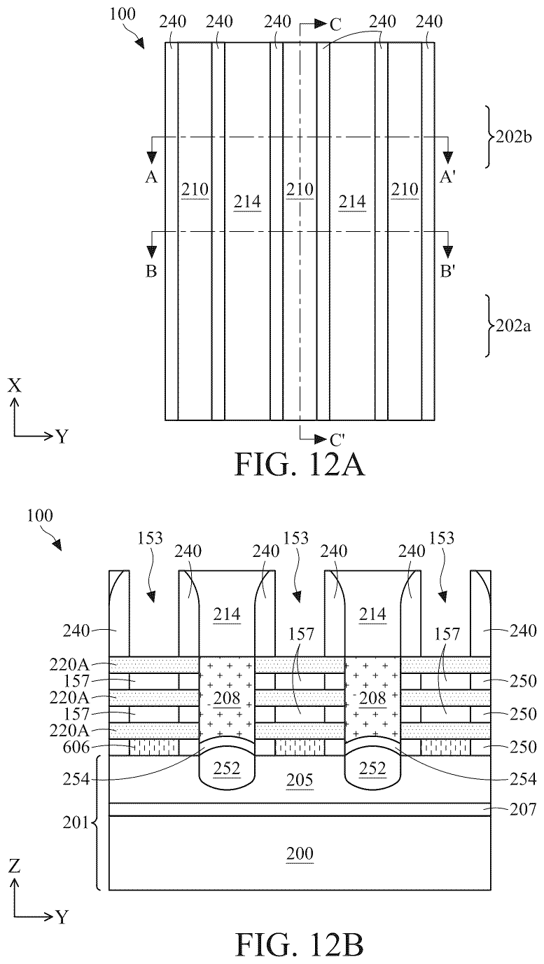

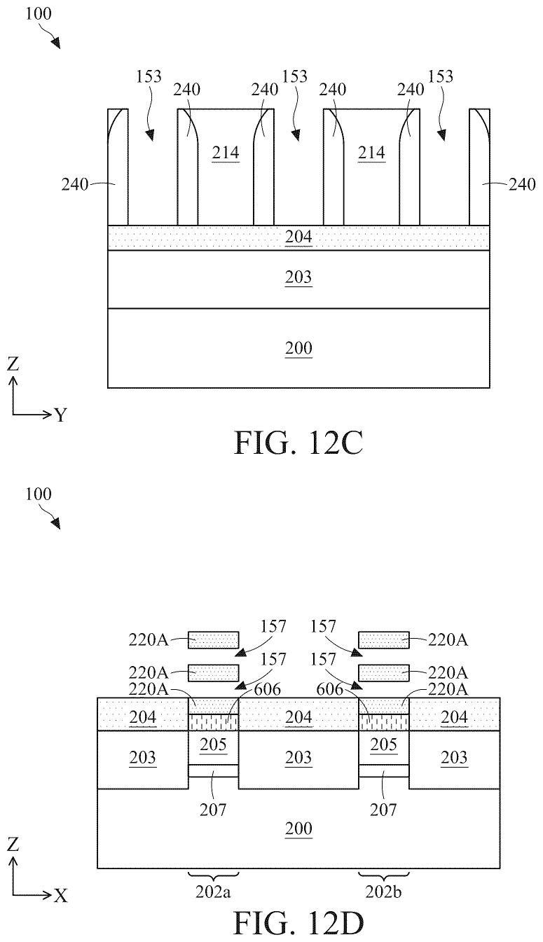

Referring to block 920 of FIG. 1C and FIGS. 12A-12D, the dielectric interposers 606 are further selectively removed through the gate trenches 153, therefore releasing the first semiconductor layers 220A as channels, for example using wet or dry etching process. The etching chemical is selected such that the dielectric interposers 606 has a sufficiently different etching rate as compared to the inner spacers 250, the hard mask 204 and the first semiconductor layers 220A. As a result, the first semiconductor layers 220A and the inner spacers 250 remain substantially unchanged. This selective etching process may include one or more etching steps. The etching process may be similar to the etching process at the block 866. For example, the etching process includes a wet etching step using HF solution to selectively remove the dielectric interposers 606.

As illustrated in FIGS. 12A-12D, in the present embodiment, the removal of the dielectric interposers 606 forms suspended semiconductor layers 220A and openings 157 in between the vertically adjacent layers (e.g. in the Z-direction), thereby exposing the top surfaces of the first semiconductor layers 220A. Each of the first semiconductor layers 220A are now exposed circumferentially in the X-Z plane.

Particularly, as the interposers 606 are different from the inner spacers 250 and the hard mask 204 in composition, and the bottommost interposers 606 are embedded in the hard mask 204, the etching process will remove all interposers 606 except for the bottommost interposers 606, functioning as self-protecting isolators (SPI, still be referred to by the numeral 606), which further provide isolation function and also provide protection to the gate structures when the backside contacts are formed during the backside process, which will be further described later. Thus, only a subset of the interposers 606 are removed, and the remaining bottommost interposers 606 serving as self-protecting isolators.

A gate structure is formed. The gate structure includes a gate dielectric layer and a gate electrode disposed over the gate dielectric layer. For example, the gate structure may include a polysilicon gate electrode over a SiON gate dielectric layer. As another example, the gate structure may include a metal gate electrode over a high-k dielectric layer. In some instances, a refractory metal layer may interpose between the metal gate electrode (such as an aluminum gate electrode) and the high-k dielectric layer. As yet another example, the gate structure may include silicide. In the depicted embodiment, the gate structures each includes a gate dielectric layer and a gate electrode that includes one or more metal layers. The gate dielectric layers are formed between the metal layers and the channels formed by the semiconductor layers 220A.

Referring to block 930 of FIG. 1C, FIGS. 13A-13D, the gate dielectric layers 228 are formed conformally on the device 100 (see FIGS. 13A-13D). The gate dielectric layers 228 at least partially fill the gate trenches 153. In some embodiments, dielectric interfacial layers may be formed over the semiconductor layers 220A prior to forming the gate dielectric layers 228. Such dielectric interfacial layers improve the adhesion between the semiconductor layers 220A and the gate dielectric layers 228. In the examples depicted in this disclosure, such dielectric interfacial layers are omitted. Instead, in the embodiments shown, the gate dielectric layers 228 is formed around the exposed surfaces of each of the semiconductor layers 220A, such that they wrap around the semiconductor layers 220A in 360 degrees. Additionally, the gate dielectric layers 228 also directly contact sidewalls of the inner spacers 250 and sidewalls of the top spacers 240. The gate dielectric layers 228 may include a dielectric material having a dielectric constant greater than a dielectric constant of SiO₂, which is approximately 3.9. For example, the gate dielectric layers 228 may include hafnium oxide (HfO₂), which has a dielectric constant in a range from about 18 to about 40. As various other examples, the gate dielectric layers 228 may include ZrO₂, Y₂O₃, La₂O₅, Gd₂O₅, TiO₂, Ta₂O₅, HfErO, HfLaO, HfYO, HfGdO, HfAlO, HfZrO, HfTiO, HfTaO, SrTiO, or combinations thereof. The formation of the gate dielectric layers 228 may be by any suitable processes, such as CVD, PVD, ALD, or combinations thereof.

Referring to block 940 of FIG. 1C and FIGS. 13A-13D, metal layers 230, 232 are formed over the gate dielectric layers 228 to fill the remaining spaces of the gate trenches 153. The metal layers 230, 232 may include any suitable materials, such as titanium nitride (TiN), tantalum nitride (TaN), titanium aluminide (TiAl), titanium aluminum nitride (TiAlN), tantalum aluminide (TaAl), tantalum aluminum nitride (TaAlN), tantalum aluminum carbide (TaAlC), tantalum carbonitride (TaCN), aluminum (Al), tungsten (W), copper (Cu), cobalt (Co), nickel (Ni), platinum (Pt), or combinations thereof. In some embodiments, a CMP is performed to expose a top surface of the ILD 214. The gate dielectric layers 228 and the metal layers 230 collectively form the gate structures 270 (such as gate structures n-type FETs), while the gate dielectric layers 228 and the metal layers 232 collectively form gate structure 272 (such as gate structures for p-type FETs). Each of the gate structures 270, 272 engages multiple nanochannels 220A.

The gate electrode may include Ti, Ag, Al, TiAlN, TaC, TaCN, TaSiN, Mn, Zr, TiN, TaN, Ru, Mo, Al, WN, Cu, W, Ru, Co, or any suitable conductive materials. In some embodiments, different metal materials are used for pFET and nFET devices with respective work functions to enhance device performances and reduce threshold voltages.

The gate electrode may include multiple conductive materials, such as a work function metal layer different for pFET and nFET devices, and a fill metal layer. In some embodiments, the gate electrode includes a capping layer, a blocking layer, a work function metal layer, and a filling metal layer. In furtherance of the embodiments, the capping layer includes titanium nitride, tantalum nitride, or other suitable material, formed by a proper deposition technique such as ALD. The blocking layer includes titanium nitride, tantalum nitride, or other suitable material, formed by a proper deposition technique such as ALD. In various embodiments, the filling metal layer includes aluminum, tungsten, copper or other suitable metal. The filling metal layer is deposited by a suitable technique, such as PVD, plating or a combination thereof.

The work functional metal layer includes a conductive layer of metal or metal alloy with proper work function such that the corresponding FET is enhanced for its device performance. The work function (WF) metal layer is different in composition for a pFET device and a nFET device, therefore being referred to as an p-type WF metal and a n-type WF metal, respectively. Particularly, an n-type WF metal is a metal having a first work function such that the threshold voltage of the associated nFET is reduced. The n-type WF metal is close to the silicon conduction band energy (Ec) or lower work function, presenting easier electron escape. For example, the n-type WF metal has a work function of about 4.2 eV or less. A p-type WF metal is a metal having a second work function such that the threshold voltage of the associated pFET is reduced. The p-type WF metal is close to the silicon valence band energy (Ev) or higher work function, presenting strong electron bonding energy to the nuclei. For example, the p-type work function metal has a WF of about 5.2 eV or higher. In some embodiments, the n-type WF metal includes tantalum (Ta). In other embodiments, the n-type WF metal includes titanium aluminum (TiAl), titanium aluminum nitride (TiAlN), or combinations thereof. In other embodiments, the n-metal include Ta, TiAl, TiAlN, tungsten nitride (WN), or combinations thereof. In some embodiments, the p-type WF metal includes titanium nitride (TiN) or tantalum nitride (TaN). In other embodiments, the p-metal include TiN, TaN, tungsten nitride (WN), titanium aluminum (TiAl), or combinations thereof. The work function metal is deposited by a suitable technique, such as PVD. The n-type WF metal or the p-type WF metal may include various metal-based films as a stack for optimized device performance and processing compatibility.

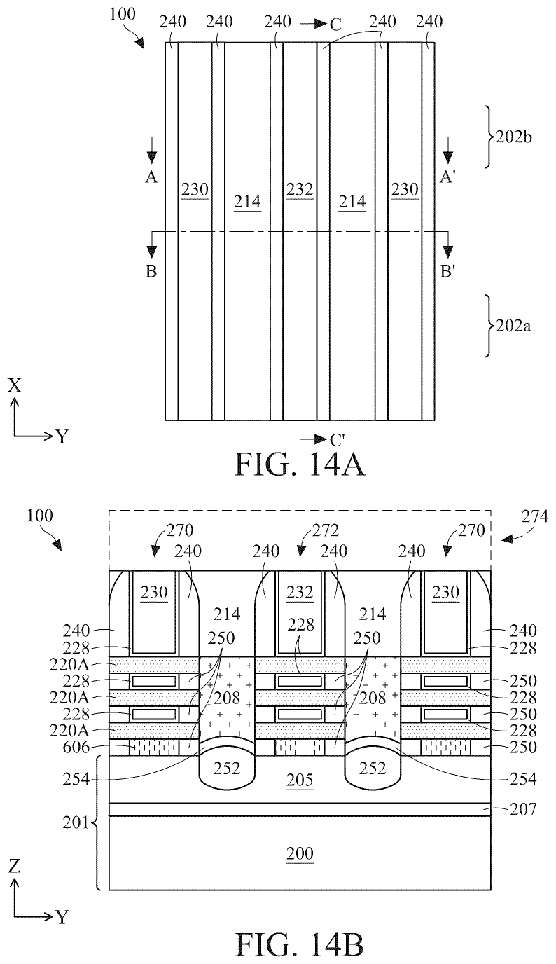

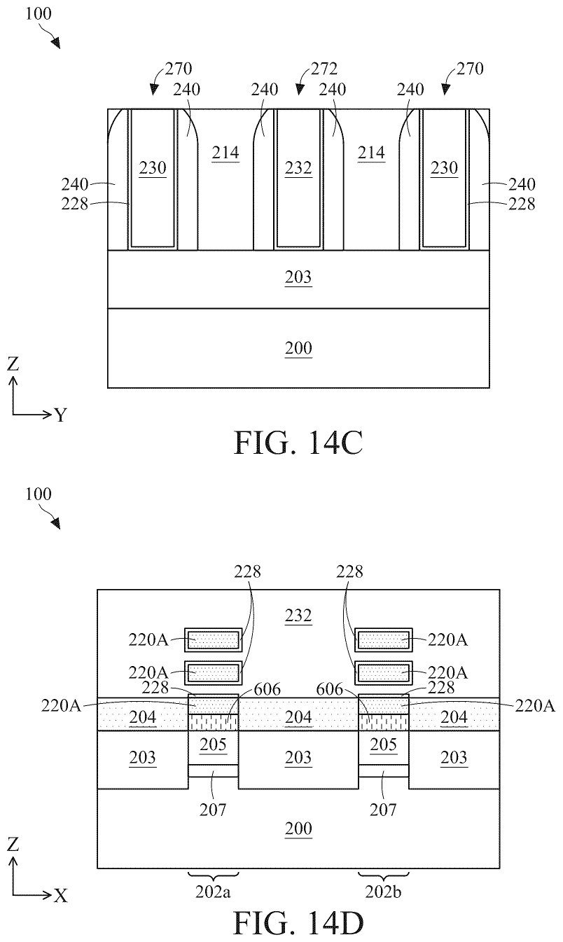

Referring to block 952 of FIG. 1D, FIGS. 14A-14D, various features are formed on the frontside of the substrate 200. For example, an interconnect structure 274, as illustrated in FIGS. 14B through 14D, to connect various FETs and other devices is formed into an integrated circuit. The interconnect structure 274 is not shown in FIG. 14A for better view of other underlying features. The interconnect structure includes contacts, vias and metal lines through a suitable process. In the copper interconnect structure, the conductive features include copper and may further include a barrier layer. The copper interconnect structure is formed by a damascene process. A damascene process includes depositing an ILD layer; patterning the ILD layer to form trenches; depositing various materials (such as a barrier layer and copper); and performing a CMP process. A damascene process may be a single damascene process or a dual damascene process. The deposition of the copper may include PVD to form a seed layer and plating to form bulk copper on the copper seed layer. Other metals, such as ruthenium, cobalt, tungsten or aluminum, may be used to form to form the interconnection structure. In some embodiments, prior to filling conductive material in contact holes, silicide may be formed on the sources and drains to further reduce the contact resistance. The silicide includes silicon and metal, such as titanium silicide, tantalum silicide, nickel silicide or cobalt silicide. The silicide may be formed by a process referred to as self-aligned silicide (or salicide). The process includes metal deposition, annealing to react the metal with silicon, and etching to remove unreacted metal. In some other embodiments, some other metal, such as ruthenium or cobalt, may be used for contacts and/or vias.

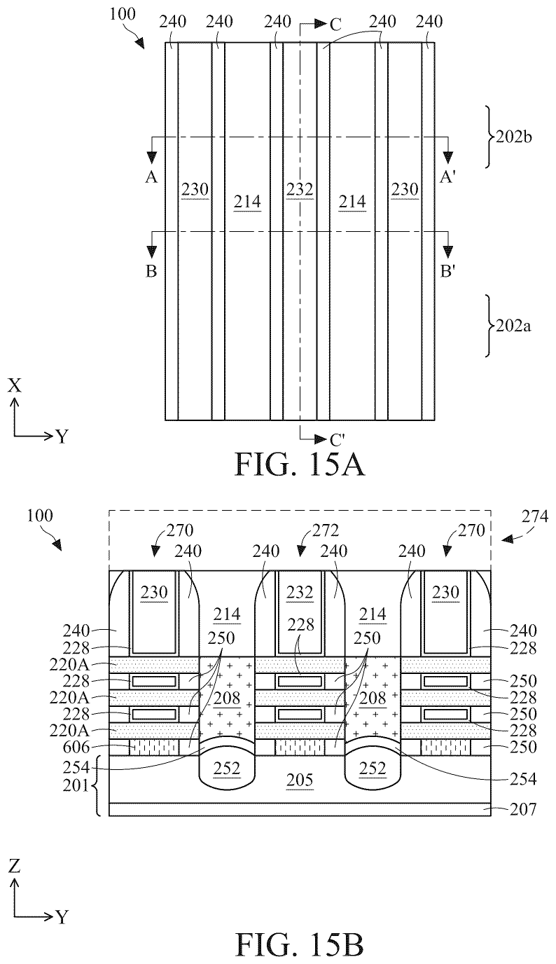

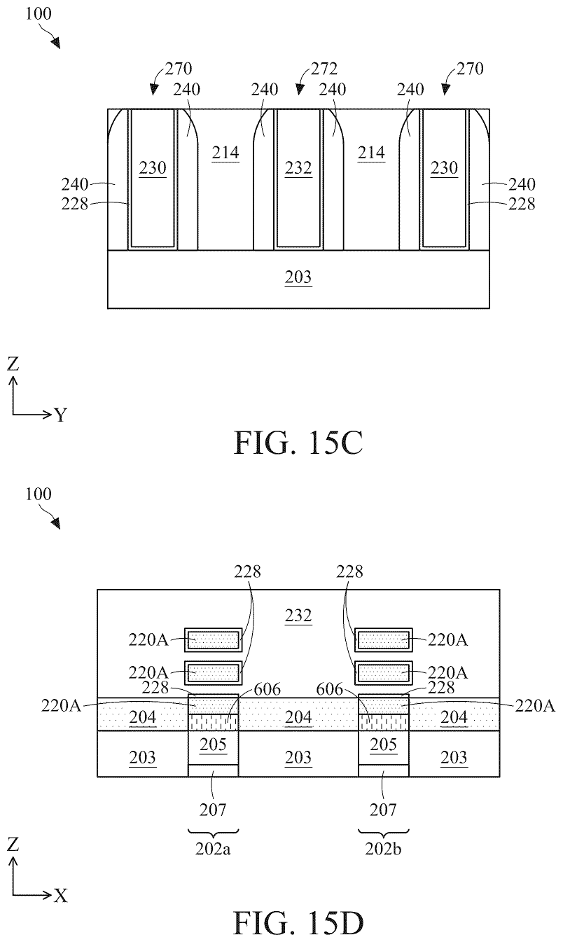

Referring to block 954 of FIG. 1D, FIGS. 15A-15D, the substrate 200 is thinned down using the semiconductor layer 207 as the stop layer. The thinning down process may include grinding and a CMP process. The semiconductor layer 207 functions as a stop layer to the thinning-down process. In the disclosed embodiment, another substrate (such as a silicon substrate, not shown) is bonded to the frontside of the workpiece before the thinning-down process.

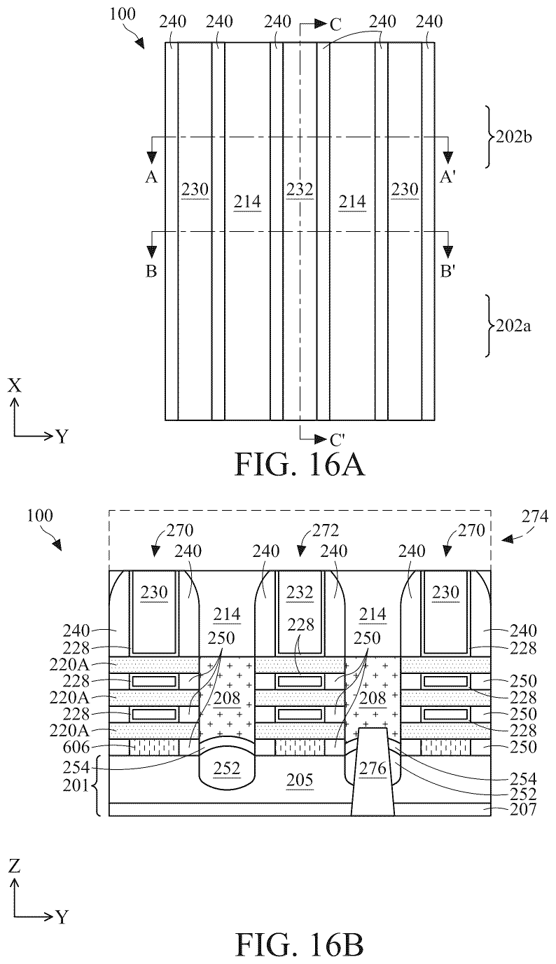

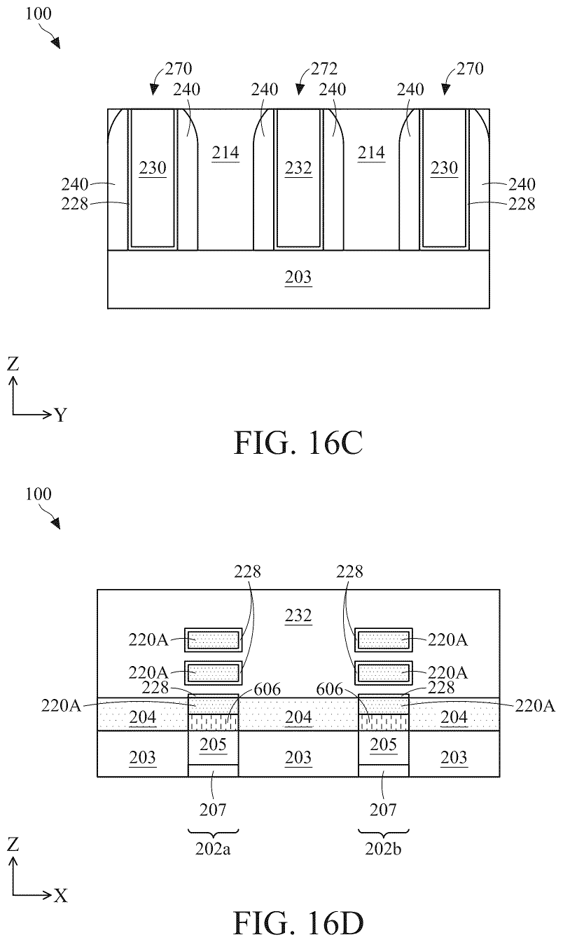

Referring to block 956 of FIG. 1D, FIGS. 16A-16D, a backside interconnect structure is formed on the backside of the substrate 200. The backside interconnect structure includes contacts, metal lines, and vias configured into the integrated circuit. For example, a contact 276 is formed on the backside of the substrate and landing on the bottom surface of a source/drain feature 208, thereby providing electrical routing to the source/drain feature 208 from the backside.

The formation of the backside contact 276 is similar to the formation of the frontside contact and includes patterning process and deposition. The patterning process includes lithography process and etching. For example, the method includes forming a patterned mask layer by a lithography process, wherein the patterned mask layer includes an opening aligned with the corresponding source/drain feature 208; performing an etching process to various materials, including the semiconductor feature 252 and the bottom isolation feature 254, to expose the source/drain feature 208; and filling one or more conductive material, thereby forming the backside contact 276. The etching process may include one or more etch steps with respective etchants to selectively etch respective materials. The method may further include a CMP process to planarize the surface and remove excessive deposited conductive material. The backside contact 276 may include a barrier layer, such as a titanium and titanium nitride, or tantalum and tantalum nitride; and a filling metal (such as tungsten, copper, aluminum, or other suitable metal or metal alloy, or a combination thereof) disposed on the barrier layer. The lithography process may have some misalignment so that the backside contact 276 is shifted, such as shifted close to the location of the gate structure. In usual case, this may cause bridging between the backside contact 276 and the gate structure and short between the source/drain feature 208 and the gate structure. However, in the disclosed structure with the self-protecting isolator (SPI) 606, the SPI 606 can effectively protect the gate structure from the etching loss if any misalignment. Various benefits may present. In addition to the elimination of the short issue, the gate structure is raised, which places the gate structure away from the backside contact and further reduce the possibility of short between backside contact and gate electrode. Furthermore, the disclosed structure also enhances strain effect. The simulation shows that more vertical channels, more stress on top channels. Therefore, even the number of channels is N-m but the stress is similar to N normal channels and greater than normal N-m channels, wherein N is the number of the channel layers and m is the number of the SPI layers. In the present embodiment, only one layer of SPI and m is 1. In the disclosed embodiment, the backside contact 276 includes greater dimensions and a greater contact size to reduce the contact resistance, due to more free spacing on the backside to enlarge its dimensions and size. In some embodiments, the backside contact 276 includes a contact surface area equal to or greater than the bottom surface area of the corresponding source/drain feature 208.

The method 800 may include other processing steps 958 implemented before, during and/or after the various operations described above.

The IC structure 100 and the method 800 making the same are described above according to some embodiments. However, the IC structure 100 may have some variations without departure of the present disclosure.

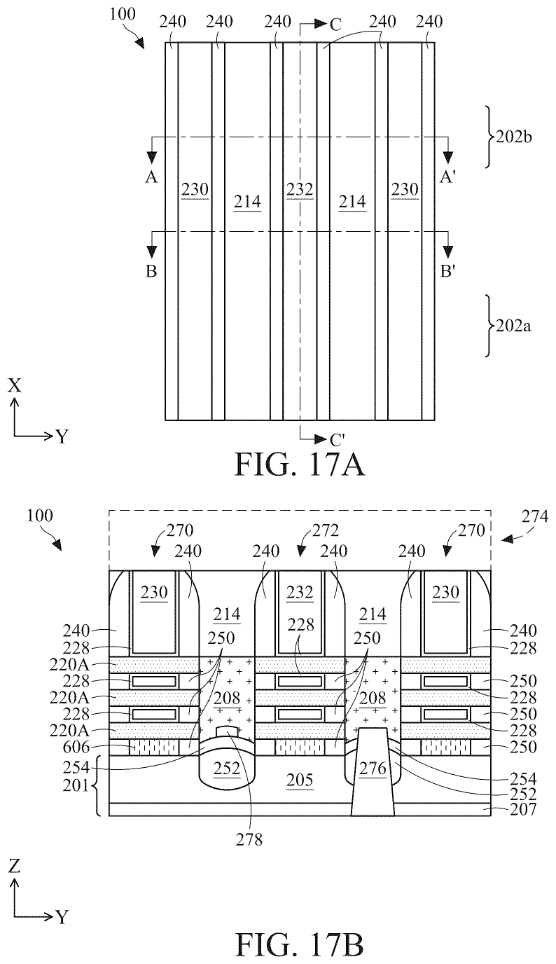

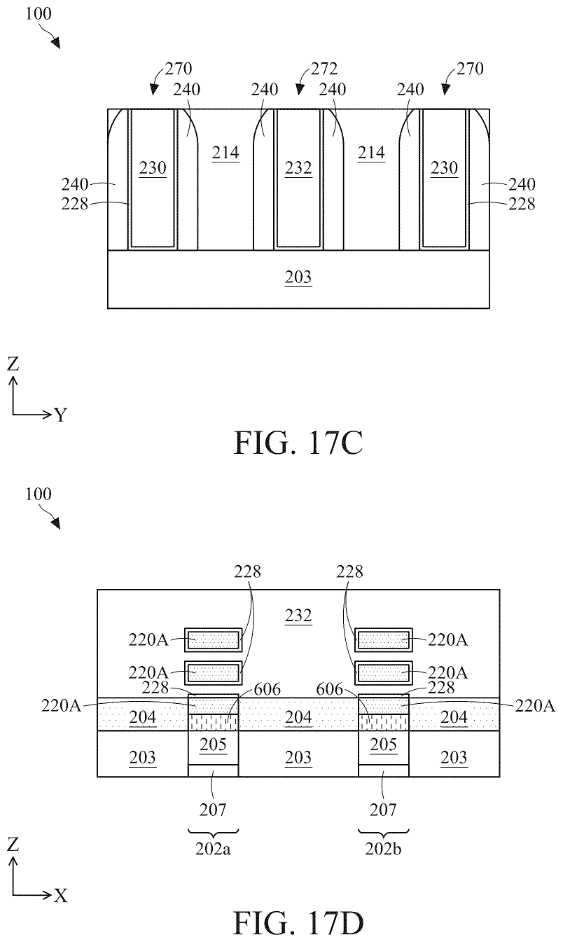

In some embodiments, referring to FIGS. 17A-17D, the IC structure 100 may include airgaps 278 underlying the source/drain features 208, as illustrated in FIG. 17B. This is formed due to the selective epitaxial growth during the formation of the source/drain features 208. Since the presence of the bottom isolation feature 254, the selective epitaxial growth will extend from the channels 220A of semiconductor material and gradually merge over the bottom isolation feature 254, thereby forming an airgap 278 vertically between the source/drain feature 208 and the bottom isolation feature 254, in certain epitaxial growth condition, such as fast growth rate.

Similar IC structure 100 is also illustrated in FIG, 18 according to some embodiments. FIG. 18 is a sectional view of the IC structure, in portion. Particularly, the airgaps 278 are also formed between the source/drain feature 208 and the bottom isolation feature 254. In FIG. 18, frontside contacts 282 are shown. Especially, silicide features 280 are formed on the source/drain features 208, and the frontside contacts 282 are formed on the silicide features 280. The backside contact may also be formed on the backsides of the substrate. For example, some frontside contacts are formed on the frontside to a subset of the source/drain features 208 and some backside contacts are formed on the backside to another subset of the source/drain features 208. In some embodiments, the semiconductor features 252 may be eliminated from the IC structure if the bottom isolation features 254 can provide enough isolation. In the disclosed embodiment, each of the gate structures 270 and 272 includes a high-k dielectric layer, a work function metal layer disposed on the high-k dielectric layer, and a fill metal layer disposed on the work function metal layer, each of those layers being V-shaped as illustrated in FIG. 18.

In some embodiments, referring to FIG. 19, the IC structure 100 may include two or more SPI layers, which further raise the gate structure and provide additional protection to the gate structure. In the illustrated embodiment, two layers of the SPI 606 are present, in which case m=2. However, the N and m can be any suitable integers such as N=5 and m=2; or N=6 and m=3; and so on. In various embodiments, a first subset of layers of the SPI 606 is removed, and a second subset of layers of the SPI 606 remains. The first subset includes N-m layers of the SPI 606, and the second subset includes m layers of the SPI 606. The N-m layers of channels are present in the final structure.

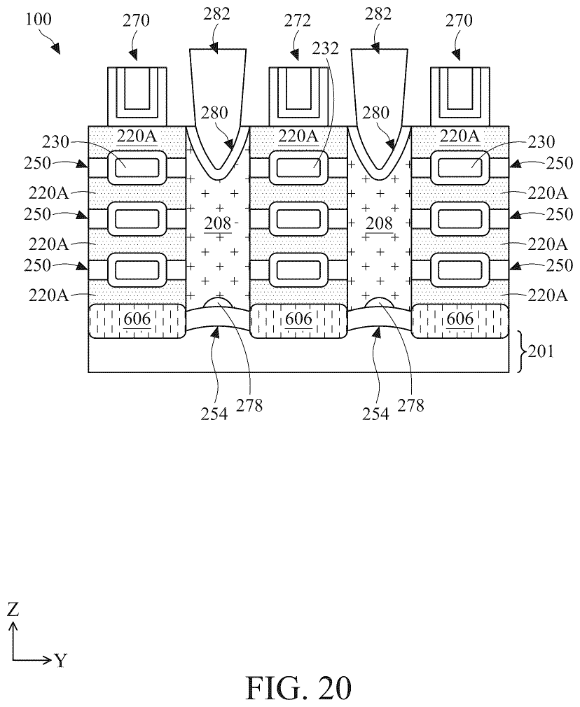

In some other embodiments, inner spacers 250 may not be formed on sides of the SPIs 606, as illustrated in FIG. 20 in a sectional view of the IC structure 100 according to some embodiments. FIG. 20 is similar to FIG. 18 except for SPIs 606 extending from source/drain feature 208 to the adjacent source/drain feature 208, or extending from bottom isolation feature 254 to the adjacent bottom isolation feature 254. The method to form the IC structure 100 in FIG. 20 is similar to the method 800 in FIGS. 1A through 1D with additional operations during the formations of the inner spacers 250, which is described in FIG. 1B. Similar descriptions are repeated. The method is described with reference to FIG. 21 and 22A through 22H. FIG. 21 is a flowchart of the method 800 (similar to FIG. 1B) constructed according to some embodiments. FIGS. 22A through 22H are sectional views of the IC structure 100 (similar to FIGS. 8A through 8H) constructed according to some embodiments.

The method 800 proceeds to operations 860 through 876 in FIGS. 22A through 22H, which are associated with processing steps applied in the trenches 151 and designed to reduce the residues and enhance the channel performance. Only FIGS. 22A through 22H in sectional views along AA′ are illustrated for simplicity. Especially, the operations 860 through 876 begin with FIG. 22A, which is similar to FIG. 7B, although the number of the semiconductor layers 220A and the number of the semiconductor layers 220B may be shown differently. As noted above, there may be any appropriate number of layers in the stack. Furthermore, the substrate 200, the semiconductor layers 205 and 207 are shown in FIG. 22A and collectively referred by the numeral 200 and are further eliminated in the following drawings for simplicity. FIG. 22A is a duplicate of FIG. 7B. It is understood that those semiconductor layers and the substrate are present, as illustrated in the previous figures, such as FIGS. 7A-7D.

Referring to block 860 of FIG. 21 and FIG. 22B, the semiconductor layers 220B are removed through the trenches 151 via a selective etching process, resulting in first gaps 602 between the semiconductor layers 220A.

Referring to block 862 of FIG. 21 and FIG. 22C, one or more dielectric material 604 is deposited to fill in the first gaps 602. The dielectric material 604 is deposited on sidewalls of the trenches 151, the sidewalls of the gate spacers 240 and the top of the gate structures 210. The dielectric material 604 may include silicon oxide, silicon nitride, silicon oxynitride, any suitable dielectric material, or a combination thereof.

Referring to block 864 of FIG. 21 and FIG. 22D, an etching process (also referred to as a first etching process) is applied the dielectric material 604, thereby removing the portions of the dielectric material 604 deposited on the sidewalls of the trenches 151, resulting in the dielectric interposers (or dummy oxide interposers) 606 in the first gaps 602. The method includes an anisotropic etch, such as a plasma etch, with etch substantially on the vertical direction. In furtherance of the embodiment, the plasma etch includes an etchant having fluorine-containing gas, chlorine-containing gas, other suitable gas or a combination thereof.

Referring to block 865 of FIG. 21 and FIG. 22E, a mask layer 286 is formed in the bottom portions of the trenches 151 so that the bottommost interposers 606 are covered and protected by the mask layer 286 from the subsequent etching. The mask layer 286 includes a material different from that of the interposers 606 to achieve etch selectivity. For example, the interposers 606 include silicon oxide and the mask layer 286 include silicon nitride or other suitable materials, such as photoresist or bottom anti-reflective coating (BARC) material. The mask layer 286 can be formed by a method similar to the formation of the bottom isolation feature 254. In the case where the mask layer 286 is photoresist or BARC material, it can be formed by a spin-on coating and etching back to recess.

Referring to block 866 of FIG. 21 and FIG. 22F, an etching process is applied to the dielectric interposers 606 so that the dielectric interposers 606 are laterally recessed through the exposed sidewall surfaces in the trenches 151 via a selective etching process. The selective etching process may be any suitable etching processes, such as a wet etching or a dry etching process. The extent to which the dielectric interposers 606 are recessed (or the size of the portion removed) is determined by the processing conditions such as the duration the dielectric interposers 606 is exposed to an etching chemical. In the depicted embodiments, the duration is controlled such that the side portions of the dielectric interposers 606 directly underlying the gate spacers 240 are removed in their entirety, while the center portions of the dielectric interposers 606 remain substantially unchanged. In other words, the remaining portions of the dielectric interposers 606 each has a sidewall that is substantially aligned with a sidewall of the dummy gate structures 210 (e.g. the sidewall in the XZ plane, defined by the X-direction and the Z-direction). As illustrated in FIG. 22F, the selective etching process creates recesses (also referred to as second gaps) 610, which extend the trenches 151 into areas beneath the semiconductor layers 220A and top spacers 240. Meanwhile, the bottommost interposers 606 remain without etching due to the protection of the mask layer 286. The etch selectivity between the first semiconductor layers 220A and the dielectric interposers 606 is made possible by the etchant and etching process. For example, the dielectric interposers 606 may be etched away at a substantially faster rate (e.g. more than about 5 times to about 10 times faster) than the mask layer 286 and the first semiconductor layers 220A. In some embodiments, the etching process is wet etching with HF solution as etchant.

Referring to block 868 of FIG. 21 and FIG. 22F, the mask layer 286 is removed by etching such as an etching process to selectively remove the mask layer 286. When the mask layer 286 is photoresist or BARC material, it can be removed by striping process or plasma ashing.

Referring to block 870 of FIG. 21 and FIG. 22G, a dielectric material 248 is filled in the second gaps 610. The method to form the dielectric material 248 includes deposition using a suitable deposition technology. The dielectric material 248 is different from the composition of the dielectric interposers 606 to achieve etch selectivity during subsequent processes, such as during the channel-release operation. In some embodiments, the dielectric material 248 may be selected from SiON, SiOC, SiOCN, other suitable dielectric material or combinations thereof. In some embodiments, the proper selection of the dielectric material may be based on its dielectric constant. In an embodiment, the dielectric material 248 may have a dielectric constant lower than that of the top spacers 240. In some other embodiments, this dielectric material may have a dielectric constant higher than that of the top spacers 240. This aspect of the dielectric material will be further discussed later. The deposition of the dielectric material may be any suitable methods, such as CVD, PVD, PECVD, MOCVD, ALD, PEALD, or combinations thereof. The operation 868 may be implemented after the operation 870 in some embodiments.

Referring to block 872 of FIG. 21 and FIG. 22H, an etching process is applied to the dielectric material 248 such that the dielectric material 248 formed on sidewalls of the trenches 151 is removed by the third etching process. The etching process includes an anisotropic etch with substantially vertical etching so that the portions of the dielectric material 246 deposited on the sidewalls and bottom surface of the trenches 151 are removed. In the depicted embodiment, the third etching process is a self-aligned anisotropic dry-etching process, such that the top spacers 240 are used as the masking element. Alternatively, a different masking element (e.g. a photoresist) may be used. The third etching process removes the dielectric materials 248 within the trenches 151 but does not substantially affect the dielectric materials 248 within the second gaps 610. As a result, the dielectric material 248 filling the second gaps 610 become inner spacers 250. In other words, the inner spacers 250 are formed in the second gaps 610 between vertically adjacent (e.g. along in the Z-direction) side portions of the first semiconductor layers 220A.

Referring to block 874 of FIG. 21 and FIG. 22H, semiconductor features 252 are formed on the bottom portions of the trenches 151. The semiconductor features 252 are undoped silicon formed by selective epitaxial growth. The semiconductor features 252, as undoped silicon, can provide isolation and avoid short to adjacent active regions.

Referring to block 876 of FIG. 21 and FIG. 22H, bottom isolation features 254 are formed on the bottom portions of the trenches 151. The bottom isolation features 254 are dielectric features to provide isolation of the source/drain features from the substrate and other conductive features, such as backside contacts. In some embodiments, the bottom isolation features 254 include silicon oxide, other suitable dielectric material (such as silicon oxynitride) or a combination thereof. In the present embodiment, the bottom isolation features 254 are formed on the semiconductor features 252. The bottom isolation features 254 and the semiconductor features 252 collectively provide effective isolation function. The bottom isolation features 254 may be formed by any suitable method, such as methods similar to the formation of the hard mask 204.

In some embodiments, the bottom isolation features 254 are formed by a method that includes deposition of one or more dielectric material to the semiconductor features 252, thereby filling the dielectric material in the trenches 151; performing a CMP process to the dielectric material; and etching to recess the dielectric material. In other embodiments, the bottom isolation features 254 is formed by a bottom-up deposition process such that the dielectric material is only deposited on the bottom surface of the trenches, such as on the semiconductor features 252. In yet other embodiments, the bottom isolation features 254 are formed by a method that includes deposition of the dielectric material; performing a plasma treatment to the deposited dielectric material such that the top portion of the deposited dielectric material is selectively treated with different composition; and performing an etching process to selectively removed the treated dielectric material so that only bottom portion of the deposited dielectric material remains on the semiconductor features 252. In furtherance of the embodiments, the plasma treatment includes a tilted plasma treatment with an angle so that only desired top portion of the dielectric material is treated. In some examples, the plasma treatment includes a plasma of proper species, such as oxygen plasma so that the treated dielectric material converts to silicon oxynitride while untreated dielectric material remains as silicon nitride.

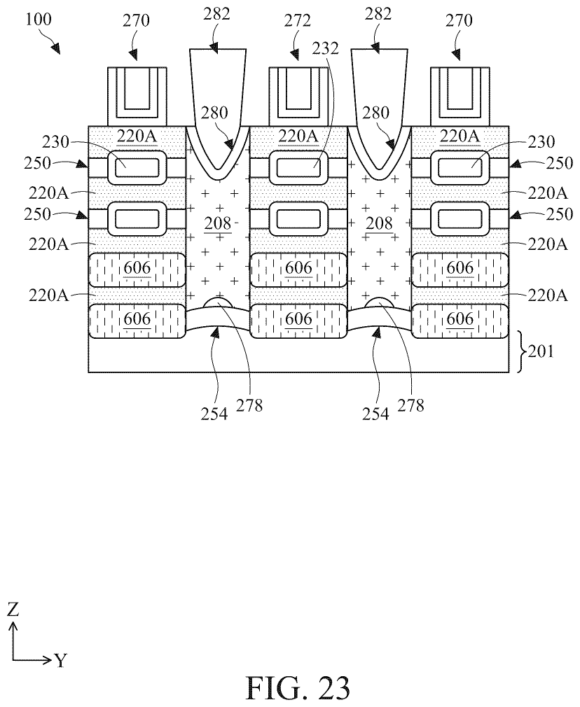

In some other embodiments, the IC structure 100 includes multiple layers of SPIs 606 and inner spacers 250 are not presented on sides of the SPIs 606, as illustrated in FIG. 23 in a sectional view of the IC structure 100 according to some embodiments. FIG. 23 is similar to FIG. 20 except for multiple layers of SPIs 606 are present and are extending from source/drain feature 208 to the adjacent source/drain feature 208 or extending from bottom isolation feature 254 to the adjacent bottom isolation feature 254. The method to form the IC structure 100 in FIG. 23 is similar to the method 800 in FIGS. 1A through 1D and FIG. 21. Similar descriptions are repeated.

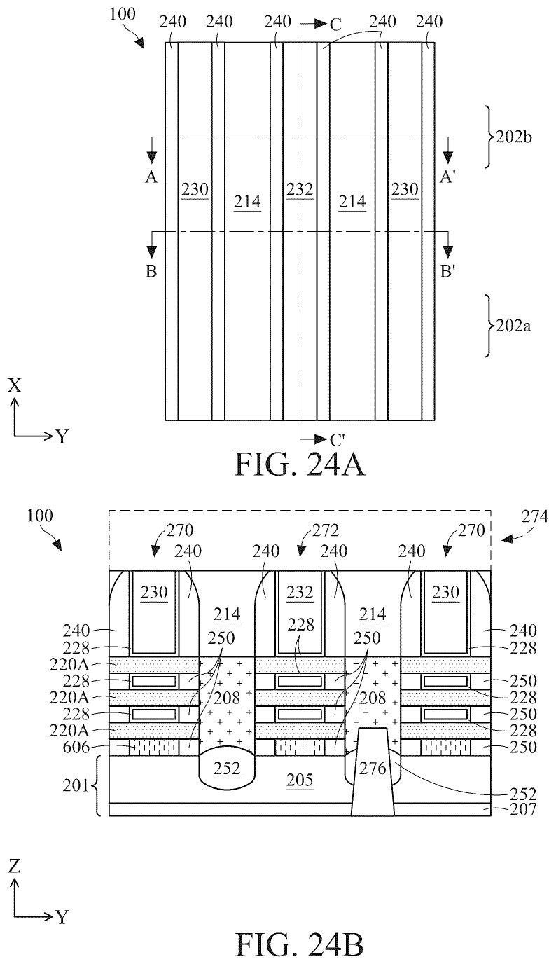

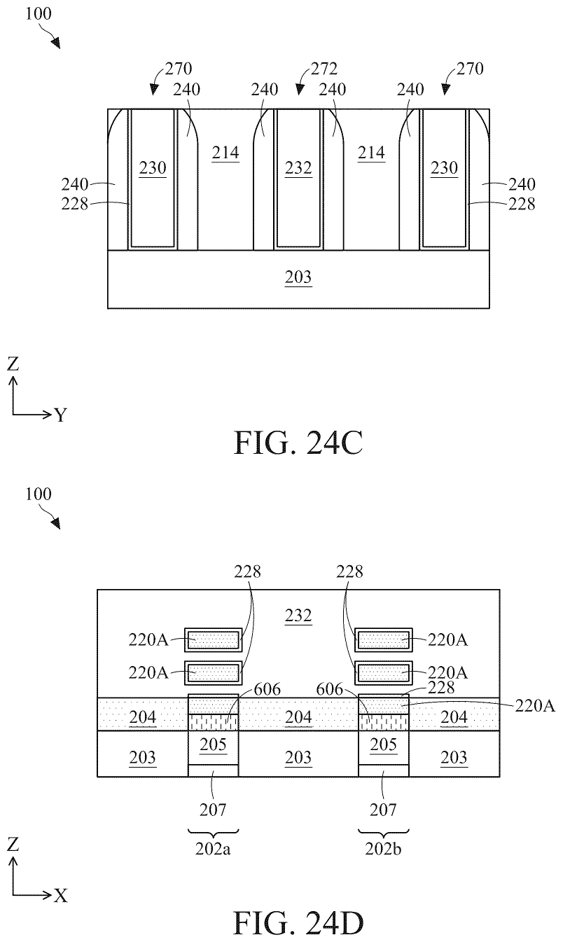

In some embodiment, the bottom isolations are eliminated as illustrated in FIGS. 24A through 24D. The method to form the IC structure 100 is similar to the IC structure 100 in other embodiments. However, the bottom isolation features 254 are eliminated and the operation in block 874 is skipped. Accordingly, the airgaps are not present.

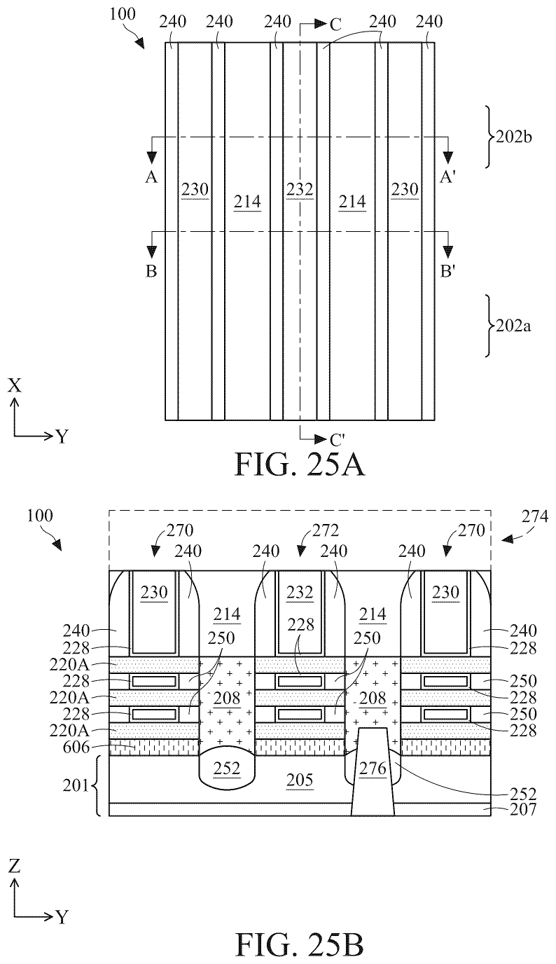

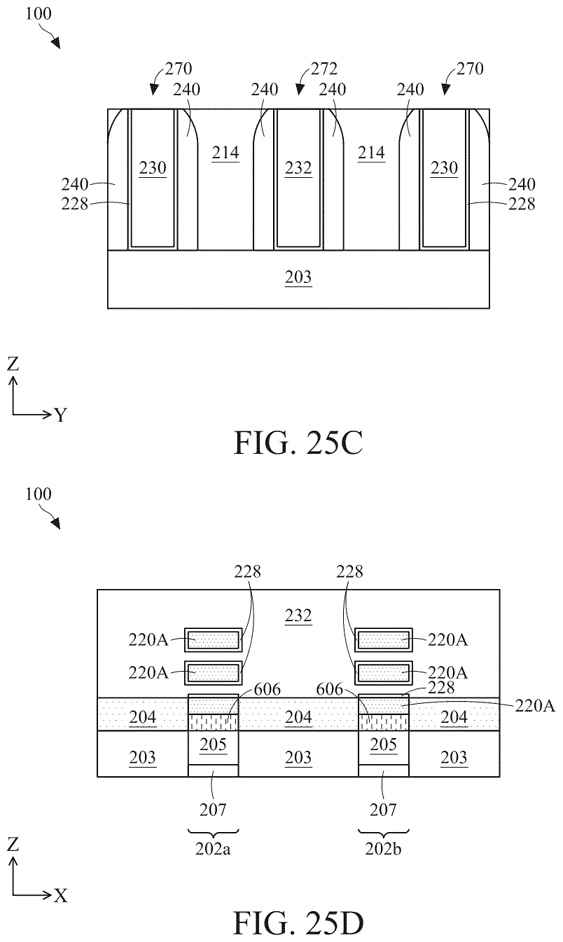

In some embodiment, the bottom isolations are eliminated as illustrated in FIGS. 25A through 25D and the bottommost inner spacers 250 next the SPIs 606 are eliminated as well. The method to form the IC structure 100 is similar to the IC structure 100 in other embodiments. The method 800 includes operations described in FIGS. 1A, 21, 1C and 1D. Furthermore, the bottom isolation features 254 are eliminated and the operation in block 874 is skipped; and the airgaps are not present.

The present disclosure provides a semiconductor structure having IC structure and a method making the same with self-protecting isolators designed to provide isolation and avoid bridging and short issues Though not intended to be limiting, embodiments of the present disclosure offer benefits for semiconductor processing and semiconductor devices. For example, the IC structure provide additional isolation and prevent from the short issue. The gate structure is raised, which places the gate structure away from the backside contact and further reduce the possibility of short between backside contact and gate electrode. Furthermore, the disclosed structure also enhances strain effect. The simulation shows that more vertical channels, more stress on top channels. Therefore, even the number of channels is N-m but the stress is similar to N normal channels and greater than normal N-m channels, wherein N is the number of the channel layers and m is the number of the SPI layers.

In one example aspect, the present disclosure provides a method that includes forming a stack including first semiconductor layers and second semiconductor layers over a semiconductor substrate, wherein the first semiconductor layers and the second semiconductor layers have different material compositions and alternate with one another within the stack; patterning the stack to form active regions; forming an isolation structure to surround the active regions; forming a hard mask on the isolation structure, the hard mask being different from the isolation structure in composition; forming a dummy gate structure over the stack; recessing source/drain regions of the stack, resulting in source/drain trenches; selectively removing the second semiconductor layers of the stack, resulting in first gaps among the first semiconductor layers; forming dielectric interposers in the first gaps; performing a first etching process to laterally recess the dielectric interposers, resulting in second gaps among the first semiconductor layers; forming inner spacers in the second gaps; forming source/drain features in the source/drain trenches; removing the dummy gate structure; and removing a subset of the dielectric interposers while bottommost dielectric interposers remain.

In another example aspect, the present disclosure provides a method. The method includes providing a stack including first semiconductor layers and second semiconductor layers over a semiconductor substrate, wherein the first semiconductor layers and the second semiconductor layers have different material compositions and alternate with one another within the stack; patterning the stack to form active regions; forming an isolation structure to surround the active regions; forming a hard mask on the isolation structure, the hard mask being different from the isolation structure in composition and the hard mask having a top surface being higher than a top surface of a bottommost one of the second semiconductor layers; forming a dummy gate structure over the stack; forming dielectric interposers among the first semiconductor layers; forming source/drain features on sides of the dummy gate structure; removing the dummy gate structure; and removing a subset of the dielectric interposers while a bottommost dielectric interposers remain.

In yet another example aspect, the present disclosure provides a semiconductor structure that includes multiple channels vertically stacked on a substrate; a gate structure wrapping around a subset of the multiple channels, source/drain features formed on sides of the gate structure; and a self-protecting isolator disposed underlying the gate structure, wherein a bottommost one of the multiple channels contacts and is vertically sandwiched between the gate structure and the self-protecting isolator.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a stack including first semiconductor layers and second semiconductor layers over a semiconductor substrate, wherein the first semiconductor layers and the second semiconductor layers have different material compositions and alternate with one another within the stack;
patterning the stack to form active regions;
forming an isolation structure to surround the active regions;
forming a hard mask on the isolation structure, the hard mask being different from the isolation structure in composition;
forming a dummy gate structure over the stack;
recessing source/drain regions of the stack, resulting in source/drain trenches;
selectively removing the second semiconductor layers of the stack, resulting in first gaps among the first semiconductor layers;
forming dielectric interposers in the first gaps;
performing a first etching process to laterally recess the dielectric interposers, resulting in second gaps among the first semiconductor layers;
forming inner spacers in the second gaps;
forming source/drain features in the source/drain trenches;
removing the dummy gate structure; and
removing a subset of the dielectric interposers while bottommost dielectric interposers remain.

2. The method of claim 1, further comprising forming a metal gate structure wrapping around a subset of the first semiconductor layers while a bottommost one of the first semiconductor layers is sandwiched by the metal gate structure and the bottommost dielectric interposers.

3. The method of claim 1, wherein
a top surface of the hard mask is above a top surface of a bottommost one of the second semiconductor layers; and
the removing of the subset of the dielectric interposers includes removing the subset of the dielectric interposers while the bottommost dielectric interposers are protected from the removal by the hard mask.

4. The method of claim 1, wherein the isolation structure includes silicon oxide, and the hard mask includes silicon nitride, wherein the forming of the hard mask includes:
depositing a dielectric material layer on the isolation structure with gaps between the active regions;
performing a plasma treatment to the dielectric material layer with a tilted angle; and
performing a second etching process to remove plasma treated portions of the dielectric material layer.

5. The method of claim 1, after the forming of the dielectric interposers, further comprising:
forming an undoped silicon layer on bottom portions of the source/drain trenches by epitaxial growth; and
forming bottom isolation features on the undoped silicon layer.

6. The method of claim 5, wherein the forming of the source/drain features further includes forming the source/drain features on the bottom isolation features and airgaps sealed between the source/drain features and the bottom isolation features.

7. The method of claim 5, after the forming of the dielectric interposers among the first semiconductor layers, further comprising:
forming a mask layer on bottom portions of the source/drain trenches, the mask layer having a top surface higher than a top surface of the bottommost dielectric interposer; and
removing the mask layer after the performing of the first etching process to laterally recess the dielectric interposers.

8. The method of claim 7, wherein the bottommost dielectric interposers laterally extend between adjacent two of the source/drain features.

9. The method of claim 1, wherein
the forming of the hard mask on the isolation structure includes forming the hard mask on the isolation structure such that a top surface of the hard mask is higher than a top surface of bottommost two of the second semiconductor layers; and
the removing of the subset of the dielectric interposers includes removing top layers of the dielectric interposers while bottommost two of the dielectric interposers remain.

10. A method, comprising:
providing a stack including first semiconductor layers and second semiconductor layers over a semiconductor substrate, wherein the first semiconductor layers and the second semiconductor layers have different material compositions and alternate with one another within the stack;
patterning the stack to form active regions;
forming an isolation structure to surround the active regions;
forming a hard mask on the isolation structure, the hard mask being different from the isolation structure in composition and the hard mask having a top surface being higher than a top surface of a bottommost one of the second semiconductor layers;
forming a dummy gate structure over the stack;
forming dielectric interposers among the first semiconductor layers;
forming source/drain features on sides of the dummy gate structure;
removing the dummy gate structure; and
removing a subset of the dielectric interposers while a bottommost dielectric interposers remain.

11. The method of claim 10, wherein the forming of the dielectric interposers among the first semiconductor layers and the forming of the source/drain features on the sides of the dummy gate structure further include;
recessing source/drain regions of the stack; resulting in source/drain trenches;
selectively removing the second semiconductor layers of the stack, resulting in first gaps among the first semiconductor layers;
forming the dielectric interposers among the first semiconductor layers;
performing a first etching process to laterally recess the dielectric interposers, resulting in second gaps among the first semiconductor layers;
forming inner spacers in the second gaps;
epitaxially growing undoped silicon features on bottom portions of the source/drain features; and
epitaxially growing the source/drain features over the undoped silicon features in the source/drain trenches.

12. The method of claim 11, after the forming of the dielectric interposers among the first semiconductor layers, further comprising:
forming a mask layer on bottom portions of the source/drain trenches; and
removing the mask layer after the performing of the first etching process to laterally recess the dielectric interposers, wherein the bottommost dielectric interposers laterally extend between adjacent two of the source/drain features.

13. The method of claim 11, further comprising forming bottom isolation features on the undoped silicon features, wherein the epitaxially growing the source/drain features includes epitaxially growing the source/drain features on the bottom isolation features, thereby sealing airgaps between the source/drain features and the bottom isolation features.

14. The method of claim 10, wherein
the isolation structure includes silicon oxide, and the hard mask includes silicon nitride; and
the removing of the subset of the dielectric interposers includes removing the subset of the dielectric interposers using an etchant selectively removes the dielectric interposers while substantially does not remove the hard mask.

15. The method of claim 10, further comprising:
forming a gate structure wrapping around of the first semiconductor layers; and
forming a backside contact disposed on a backside of the semiconductor substrate, wherein the backside contact is separated from the gate structure by the bottommost dielectric interposers.

16. The method of claim 10, wherein the forming of the hard mask includes:
depositing a dielectric material layer on the isolation structure with gaps between the active regions;
performing a plasma treatment to the dielectric material layer with a tilted angle; and
performing a second etching process to remove plasma treated portions of the dielectric material layer.

17. A semiconductor structure, comprising:
multiple channels vertically stacked on a substrate;
a gate structure wrapping around a subset of the multiple channels,
source/drain features formed on sides of the gate structure; and
a self-protecting isolator disposed underlying the gate structure, wherein a bottommost one of the multiple channels contacts and is vertically sandwiched between the gate structure and the self-protecting isolator.

18. The semiconductor structure of claim 17, further comprising bottom isolation features disposed underlying the source/drain features, sealing airgaps therebetween.

19. The semiconductor structure of claim 17, wherein the self-protecting isolator is a dielectric feature contacting and laterally extending between adjacent two of the source/drain features.

20. The semiconductor structure of claim 17, further comprising inner spacers disposed between the gate structure and the source/drain features, wherein the self-protecting isolator is a dielectric feature contacting and laterally extending between adjacent two of the inner spacers.
